(19) United States
(12) Patent Application Publication
(10) Pub. No.: US 2025/0318379 A1
(43) Pub. Date: Oct. 9, 2025

(54) DISPLAY DEVICE

(71) Applicant: Samsung Display Co., LTD., Yongin-si (KR)

(72) Inventors: Won Jun LEE, Yongin-si (KR); Chol Ho KIM, Yongin-si (KR)

(73) Assignee: Samsung Display Co., LTD., Yongin-si (KR)

(21) Appl. No.: 19/013,619

(22) Filed: Jan. 8, 2025

(30) Foreign Application Priority Data
Apr. 3, 2024 (KR) 10-2024-0045258

(51) Int. Cl. H10K 59/131

(52) U.S. Cl. CPC H10K 59/131

(57) ABSTRACT

A display device includes a substrate, first and second metal pads, sub-pixels, and metal lines. The substrate includes a display area and a non-display area. The first and second metal pads are disposed on the non-display area. The second metal pad is spaced apart from the first metal pad in a first direction. The sub-pixels are disposed on the display area and are disposed between the first metal pad and the second metal pad in a view in a third direction perpendicular to the substrate. The metal lines electrically connect the first metal pad to the second metal pad. The metal lines are disposed on the display area and are spaced apart from light emission areas of the sub-pixels in the view. The first metal pad includes first sub-metal pads spaced apart from each other. The second metal pad includes second sub-metal pads spaced apart from each other.

### CROSS-REFERENCE TO RELATED APPLICATION(S)

This U.S. non-provisional patent application claims priority to and the benefits of Korean Patent Application No. 10-2024-0045258 under 35 U.S.C. § 119, filed in the Korean Patent Intellectual Property Office on Apr. 3, 2024, the entire contents of which are hereby incorporated by reference.

### BACKGROUND

### 1. Technical Field

Various embodiments relate to a display device.

### 2. Description of Related Art

With the development of information technology, the importance of a display device, which is a connection medium between a user and information, has been emphasized. Owing to the importance of display devices, the use of various kinds of display devices, such as a liquid crystal display device and an organic light-emitting display device, has increased.

A display device may use pixels to display an image. To implement augmented reality (AR), virtual reality (VR), or mixed reality (MR), display devices may have an increased number of pixels disposed on a relatively small display surface in comparison to a conventional display device, such as a television. As the distance between pixels decreases, leakage current through a common layer of adjacent pixels may cause problems.

The background provided herein is for the purpose of generally presenting the context of the disclosure. Work of the presently named inventors, to the extent that it is described in this background section, as well as aspects of the description that may not otherwise qualify as prior art at the time of filing, are neither expressly nor impliedly admitted as prior art against the disclosure.

### SUMMARY

Various embodiments are directed to a display device capable of preventing (or at least mitigating) current leakage through a common layer between adjacent pixels.

Additional aspects will be set forth in the detailed description, which follows, and in part, will be apparent from the disclosure, or may be learned by practice of the disclosed embodiments and/or the claimed subject matter.

According to an embodiment, a display device includes a substrate, a first metal pad, a second metal pad, sub-pixels, and metal lines. The substrate includes a display area and a non-display area. The first metal pad is disposed on the non-display area. The second metal pad is disposed on the non-display area. The second metal pad is spaced apart from the first metal pad in a first direction. The sub-pixels are disposed on the display area. The sub-pixels are disposed between the first metal pad and the second metal pad in a view in a third direction perpendicular to the substrate. The metal lines electrically connect the first metal pad to the second metal pad. The metal lines are disposed on the display area. The metal lines are spaced apart from light emission areas of the sub-pixels in the view. The first metal pad includes first sub-metal pads spaced apart from each other. The second metal pad includes second sub-metal pads spaced apart from each other.

In an embodiment, first sub-metal pads of a first group among the first sub-metal pads may include openings.

In an embodiment, additional pads may be respectively exposed through the openings.

In an embodiment, first sub-metal pads of a second group among the first sub-metal pads may not include openings.

In an embodiment, second sub-metal pads of a first group among the second sub-metal pads may include openings. Some of the metal lines may electrically connect the second sub-metal pads of the first group to the first sub-metal pads of the first group.

In an embodiment, second sub-metal pads of the second group among the second sub-metal pads may not include openings. Some of the metal lines may electrically connect the second sub-metal pads of the second group respectively to the first sub-metal pads of the second group.

In an embodiment, the display device may further include a voltage generator configured to apply at least one first voltage pulse to each of the first sub-metal pads of the first group, and to apply at least one second voltage pulse to each of the first sub-metal pads of the second group.

In an embodiment, a voltage level of the at least one first voltage pulse may be less than a voltage level of the at least one second voltage pulse.

In an embodiment, a number of the at least one first voltage pulse may be greater than a number of the at least one second voltage pulse.

In an embodiment, the voltage generator may be configured to set the voltage levels and the numbers of the at least one first voltage pulse and the at least one second voltage pulse such that a power density of each of the first sub-metal pads of the first group is identical to a power density of each of the first sub-metal pads of the second group.

In an embodiment, the voltage generator may be configured to apply a third voltage to the second sub-metal pads of the first group and the second sub-metal pads of the second group. A voltage level of the third voltage may be less than the voltage level of the at least one first voltage pulse and the voltage level of the at least one second voltage pulse.

In an embodiment, the first metal pad may extend in a second direction transverse to the first direction. The third direction may be perpendicular to the first direction and the second direction. A width of each of the first sub-metal pads of the first group in the second direction may be less than a width of each of the first sub-metal pads of the second group in the second direction.

In an embodiment, the second metal pad may extend in the second direction. A width of each of the second sub-metal pads of the first group in the second direction may be less than a width of each of the second sub-metal pads of the second group in the second direction.

In an embodiment, respective distances between the substrate and the first sub-metal pads in the third direction may be greater than respective distances between the substrate and the additional pads in the third direction.

In an embodiment, the additional pads may include a first electrode layer. The first electrode layer may be part of an electrode layer among electrode layers forming sub-pixel circuits of the sub-pixels.

In an embodiment, the first sub-metal pads may include a second electrode layer. The second electrode layer may be part of an electrode layer forming anode electrodes of light-emitting elements of the sub-pixels.

In an embodiment, the first sub-metal pads may include a second electrode layer. The second electrode layer may be part of an electrode layer forming reflective electrodes. The reflective electrodes may be disposed between light-emitting elements of the sub-pixels and the substrate.

In an embodiment, the first sub-metal pads may include a second electrode layer. The second electrode layer may be part of an electrode layer forming the metal lines.

In an embodiment, the first metal pad may extend in a second direction transverse to the first direction. The first sub-metal pads may be spaced apart from one another along the second direction. Widths of the first sub-metal pads in the second direction may be identical to each other.

In an embodiment, the second metal pad may extend in the second direction. The second sub-metal pads may be spaced apart from one another along the second direction. Widths of the second sub-metal pads in the second direction may be identical to each other.

The foregoing general description and the following detailed description are illustrative and explanatory and are intended to provide further explanation of the claimed subject matter.

### BRIEF DESCRIPTION OF THE DRAWINGS

Various embodiments disclosed herein are illustrated by way of example, and not by way of limitation, in the figures of the accompanying drawings, in which like reference numerals and/or characters refer to similar elements.

FIG. 1 is a block diagram schematically illustrating an embodiment of a display device.

FIG. 2 is a plan view schematically illustrating an embodiment of the display panel of FIG. 1.

FIG. 3 is a plan view schematically illustrating an embodiment of the display panel of FIG. 1.

FIGS. 4, 5, and 6 are schematic diagrams for describing a Joule heating process in a method of fabricating the display panel of FIG. 3 according to an embodiment.

FIG. 7 is a plan view schematically illustrating an embodiment of the display panel of FIG. 1.

FIGS. 8 and 9 are schematic diagrams for describing a Joule heating process in a method of fabricating the display panel of FIG. 7 according to an embodiment.

FIG. 10 is a plan view schematically illustrating an embodiment of the display panel of FIG. 1.

FIG. 11 is a schematic diagram for describing a Joule heating process in a method of fabricating the display panel of FIG. 10 according to an embodiment.

FIG. 12 is a schematic block diagram for describing a sub-pixel according to an embodiment.

FIG. 13 is a schematic diagram for describing an embodiment of the sub-pixel.

FIG. 14 is an exploded perspective view schematically illustrating a portion of the display panel of FIG. 1.

FIG. 15 is a schematic plan view for describing a relationship between sub-pixels and metal lines according to an embodiment.

FIG. 16 is a sectional view schematically illustrating an embodiment of an emission structure.

FIG. 17 is a sectional view schematically illustrating an embodiment of the emission structure.

FIG. 18 is a schematic sectional view taken along sectional line I-I′ of FIG. 15 according to an embodiment.

FIG. 19 is a sectional view schematically illustrating an embodiment of FIG. 18.

FIG. 20 is a schematic sectional diagram taken along sectional line A-A′ of FIG. 8 according to an embodiment.

FIG. 21 is a sectional view schematically illustrating an embodiment of FIG. 20.

FIG. 22 is a block diagram schematically illustrating an embodiment of a display system.

FIG. 23 is a perspective diagram schematically illustrating an application example of the display system of FIG. 22 according to an embodiment.

FIG. 24 is a diagram schematically illustrating a head-mounted display device of FIG. 23 that is worn by a user according to an embodiment.

### DETAILED DESCRIPTION OF THE EMBODIMENTS

In the following description, for the purposes of explanation, numerous specific details are set forth to provide a thorough understanding of various embodiments or implementations. The terms “embodiments” and “implementations” may be used interchangeably to describe one or more non-limiting examples of systems, apparatuses, methods, etc., described herein. It is apparent, however, that various embodiments may be practiced without these specific details or with one or more equivalent arrangements. In other instances, known structures and devices are shown in block diagram form to avoid unnecessarily obscuring various embodiments. Further, various embodiments may be different, but do not have to be exclusive. For example, specific shapes, configurations, and characteristics of an embodiment may be used or implemented in another embodiment without departing from the teachings of the disclosure.

Unless otherwise specified, the illustrated embodiments are to be understood as providing example features of varying detail of some embodiments. Thus, unless otherwise specified, the features, components, modules, layers, films, regions, aspects, structures, etc. (hereinafter individually or collectively referred to as an “element” or “elements”), of the various illustrations may be otherwise combined, separated, interchanged, and/or rearranged without departing from the teachings of the disclosure.

The use of cross-hatching and/or shading in the accompanying drawings is generally provided to clarify boundaries between adjacent elements. As such, neither the presence nor the absence of cross-hatching or shading is intended to convey or indicate any preference or requirement for materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. As such, the sizes and relative sizes of the respective elements are not necessarily limited to the sizes and relative sizes shown in the drawings. In a case that an embodiment may be implemented differently, a specific process order may be performed differently from the described order. For example, two consecutively described processes may be performed substantially at the same time or performed in an order opposite the described order. Also, like reference numerals and/or reference characters denote like elements.

In a case that an element, such as a layer, is referred to as being “on,” “over,” “connected to (or with),” or “coupled to (or with)” another element, it may be directly on, directly over, directly connected to (or with), or directly coupled to (or with) the other element or at least one intervening element may be present. However, in a case that an element is referred to as being “directly on,” “directly over,” “directly connected to (or with),” or “directly coupled to (or with)” another element, there are no intervening elements present. Other terms and/or phrases, if used herein, to describe a relationship between elements should be interpreted in a like fashion, such as “between” versus “directly between,” “adjacent” versus “directly adjacent,” “on” versus “directly on,” “contacting” versus “directly contacting,” “touching” versus “directly touching,” etc. Further, the term “connected” may refer to physical, electrical, and/or fluid connection. To this end, for the purposes of this disclosure, the phrase “fluidically connected” may be used with respect to volumes, plenums, holes, openings, etc., that may be connected to one another, either directly or via one or more intervening components or volumes, to form a fluidic connection, similar to how the phrase “electrically connected” is used with respect to components that are connected to form an electric connection.

For the purposes of this disclosure, a first axis extending along a first direction DR1, a second axis extending along a second direction DR2, and a third axis extending along a third direction DR3 are not limited to three axes of a rectangular coordinate system, such as x, y, and z axes of a Cartesian coordinate system, and may be interpreted in a broader sense. For example, the first axis, the second axis, and the third axis may be perpendicular to one another, or may represent different directions that are not perpendicular to one another. Further, if used herein, the phrases “at least one of X, Y, . . . , and Z” and “at least one selected from the group consisting of X, Y, . . . , and Z” may be construed as X only, Y only, . . . , Z only, or any combination of two or more of X, Y, . . . , and Z, such as, for instance, XYZ, XYY, YZ, and ZZ. Also, if used herein, the term “and/or” includes any and all combinations of one or more of the associated listed items.

Although the terms “first,” “second,” “third,” etc., may be used herein to describe various elements, these elements should not be limited by these terms. These terms are used to distinguish one element from another element. Thus, a first element discussed below could be termed a second element without departing from the teachings of the disclosure. To this end, use of such identifiers, e.g., “a first element,” should not be read as suggesting, implicitly or inherently, that there is necessarily another instance, e.g., “a second element.”

Spatially relative terms, such as “beneath,” “below,” “under,” “lower,” “above,” “upper,” “over,” “higher,” “side” (e.g., as in “sidewall”), and the like, may be used herein for descriptive purposes, and thereby, to describe one element's spatial relationship to at least one other element as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” or “over” the other elements or features. Thus, the term “below” can encompass both an orientation of above and below. Furthermore, the apparatus may be otherwise oriented (e.g., rotated 90 degrees or at other orientations), and as such, the spatially relative descriptors used herein interpreted accordingly.

The terminology used herein is for the purpose of describing some embodiments and is not intended to be limiting. As used herein, the singular forms, “a,” “an,” and “the” are intended to include the plural forms as well, unless the context clearly indicates otherwise. It is to be understood that the phrases “for each <item> of the one or more <items>,” “each <item> of the one or more <items>,” and/or the like, if used herein, are inclusive of both a single-item group and multiple-item groups, i.e., the phrase “for . . . each” is used in the sense that it is used in programming languages to refer to each item of whatever population of items is referenced. For example, if the population of items referenced is a single item, then “each” would refer to only that single item (despite dictionary definitions of “each” frequently defining the term to refer to “every one of two or more things”) and would not imply that there must be at least two of those items. Similarly, the term “set” or “subset” should not be viewed, in and of itself, as necessarily encompassing a plurality of items—it is to be understood that a set or a subset can encompass only one member or multiple members (unless the context indicates otherwise).

The terms “comprises,” “comprising,” “includes,” “including,” “has,” “have,” and/or “having” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” “approximately,” and other similar terms, are used as terms of approximation and not as terms of degree, and as such, are utilized to account for inherent deviations in measured, calculated, and/or provided values that would be recognized by one of ordinary skill in the art. Accordingly, the term “substantially,” if used herein, and unless otherwise specified, may mean within 5% of a referenced value. For example, substantially perpendicular may mean within ±5% of being parallel. Moreover, the term “between,” if used herein in association with a range of values, is to be understood, unless otherwise indicated, as being inclusive of the start and end values of the range. For example, between 1 and 5 is to be understood as being inclusive of the numbers 1, 2, 3, 4, and 5, not just the numbers 2, 3, and 4. Furthermore, the expression “being the same” may mean “being substantially the same.” For instance, the expression “being the same” may include a range that can be tolerated by those skilled in the art. Other expressions may also be expressions from which “substantially” has been omitted.

Various embodiments are described herein with reference to sectional views, isometric views, perspective views, orthographic views, and/or exploded illustrations that are schematic depictions of idealized embodiments and/or intermediate structures. As such, variations from the shapes of the illustrations because of, for example, manufacturing techniques and/or tolerances, are to be expected. Thus, embodiments disclosed herein should not be construed as limited to the illustrated shapes of regions, but are to include deviations in shapes that result from, for instance, manufacturing. To this end, regions illustrated in the drawings may be schematic in nature and shapes of these regions may not reflect the actual shapes of regions of a device, and as such, are not intended to be limiting.

As customary in the field, some embodiments may be described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the disclosure. Further, the blocks, units, and/or modules of some embodiments may be physically combined into more complex blocks, units, and/or modules without departing from the scope of the disclosure.

Unless otherwise defined, all terms (including technical and scientific terms) used herein have the same meaning as commonly understood by one of ordinary skill in the art to which this disclosure pertains. Terms, such as those defined in commonly used dictionaries, should be interpreted as having a meaning that is consistent with their meaning in the context of the relevant art and are not to be interpreted in an idealized or overly formal sense, unless expressly so defined herein.

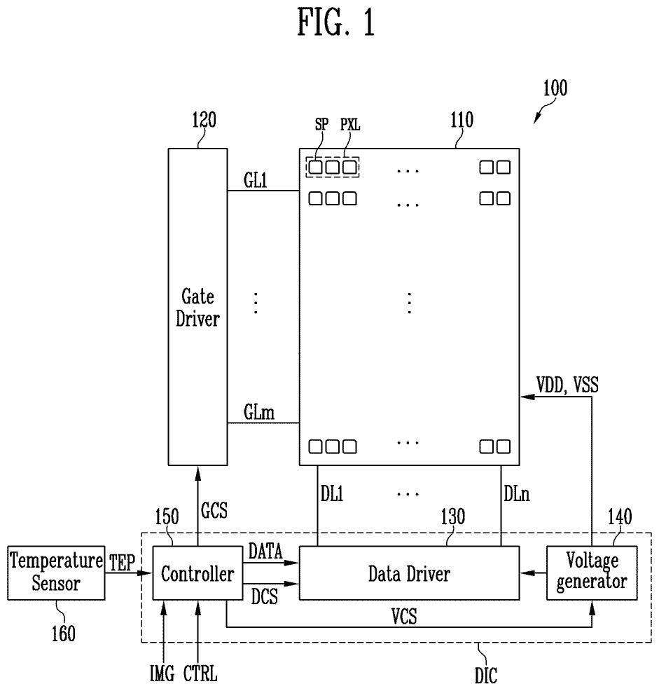

FIG. 1 is a block diagram schematically illustrating an embodiment of a display device 100.

Referring to FIG. 1, the display device 100 may include a display panel 110, a gate driver 120, a data driver 130, a voltage generator 140, and a controller 150.

The display panel 110 may include sub-pixels SP. The sub-pixels SP may be electrically connected to the gate driver 120 through first to m-th gate lines GL1 to GLm, where “m” in a positive integer greater than one. The sub-pixels SP may be connected to the data driver 130 through first to n-th data lines DL1 to DLn, where “n” is a positive integer greater than one.

Each of the sub-pixels SP may include at least one light-emitting element configured to generate light. Each of the sub-pixels SP may generate light of a specific color, such as red, green, blue, cyan, magenta, or yellow, but embodiments are not limited to these example colors. Two or more sub-pixels among the sub-pixels SP may form one (or a) pixel PXL. For example, as illustrated in FIG. 1, three sub-pixels may form one pixel PXL.

The gate driver 120 may be electrically connected to sub-pixels SP arranged in a row direction through the first to m-th gate lines GL1 to GLm. The gate driver 120 may output gate signals to the first to m-th gate lines GL1 to GLm in response to a gate control signal GCS. In embodiments, the gate control signal GCS may include a start signal instructing each frame to start, a horizontal synchronization signal for outputting gate signals in synchronization with a timing at which data signals are applied, and/or the like.

The gate driver 120 may be disposed on one (or a) side of the display panel 110. However, embodiments are not limited to the aforementioned example. For example, the gate driver 120 may be divided into (or include) two or more drivers that are physically and/or logically distinguished from each other. The drivers may be disposed on a first side of the display panel 110 and a second side of the display panel 110 opposite to the first side. As such, the gate driver 120 may be disposed around the display panel 110 in various forms depending on embodiments.

The data driver 130 may be electrically connected to sub-pixels SP arranged in a column direction through the first to n-th data lines DL1 to DLn. The data driver 130 may receive image data DATA and a data control signal DCS from the controller 150. The data driver 130 may operate in response to the data control signal DCS. In embodiments, the data control signal DCS may include a source start pulse, a source shift clock, a source output enable signal, and/or the like.

The data driver 130 may apply, using voltages from the voltage generator 140, data signals having grayscale voltages corresponding to the image data DATA to the first to n-th data lines DL1 to DLn. In a case that a gate signal is applied to each of the first to m-th gate lines GL1 to GLm, data signals corresponding to the image data DATA may be applied to the data lines DL1 to DLn. The corresponding sub-pixels SP may generate light corresponding to the data signals. An image may be displayed on the display panel 110.

In embodiments, the gate driver 120 and the data driver 130 may include one or more complementary metal-oxide semiconductor (CMOS) circuit elements, but embodiments are not limited to this example.

The voltage generator 140 may operate in response to a voltage control signal VCS provided from the controller 150. The voltage generator 140 is configured to generate multiple voltages and provide the generated voltages to components of the display device 100. For example, the voltage generator 140 may be configured to receive an input voltage from an external device provided outside the display device 100, adjust the received voltage, and regulate the adjusted voltage, thus generating multiple voltages.

The voltage generator 140 may generate a first power voltage VDD and a second power voltage VSS. The generated first and second power voltages VDD and VSS may be provided to the sub-pixels SP. The first power voltage VDD may have a relatively high voltage level. The second power voltage VSS may have a voltage level lower than the first power voltage VDD. In some embodiments, the first power voltage VDD or the second power voltage VSS may be provided by an external device that is external to the display device 100.

In some embodiments, the voltage generator 140 may generate various voltages. For example, the voltage generator 140 may generate an initialization voltage to be applied to the sub-pixels SP. For example, as part of a sensing operation for sensing electrical characteristics of transistors and/or light-emitting elements of the sub-pixels SP, a reference voltage may be applied to each of the first to n-th data lines DL1 to DLn. The voltage generator 140 may generate the reference voltage.

The controller 150 may control overall operations of the display device 100. The controller 150 may receive input image data IMG and a control signal CTRL for controlling an operation of displaying the input image data IMG from an external device. The controller 150 may provide a gate control signal GCS, a data control signal DCS, and a voltage control signal VCS in response to the control signal CTRL.

The controller 150 may convert the input image data IMG to be suitable for the display device 100 or the display panel 110 and output image data DATA to, for example, the data driver 130. In embodiments, the controller 150 may align the input image data IMG to be suitable for an arrangement of the sub-pixels SP and output the image data DATA to, for example, the data driver 130.

Two or more components of the data driver 130, the voltage generator 140, and the controller 150 may be mounted on (or incorporated as part of) a single integrated circuit. As illustrated in FIG. 1, the data driver 130, the voltage generator 140, and the controller 150 may be included in a driver integrated circuit DIC. The data driver 130, the voltage generator 140, and the controller 150 may be components that are functionally separate from each other in the single driver integrated circuit DIC. In some embodiments, at least one of the data driver 130, the voltage generator 140, and the controller 150 may be provided as a component separate from the driver integrated circuit DIC.

In an embodiment, the display device 100 may include at least one temperature sensor 160. The temperature sensor 160 is configured to sense a peripheral temperature and generate temperature data TEP indicating the sensed temperature. In embodiments, the temperature sensor 160 may be disposed adjacent to the display panel 110 and/or the driver integrated circuit DIC.

The controller 150 may control various operations of the display device 100 in response to the temperature data TEP. In embodiments, the controller 150 may adjust the luminance of an image output from the display panel 110 in response to the temperature data TEP. For example, the controller 150 may control components such as the data driver 130 and/or the voltage generator 140, thus adjusting data signals and the first and second power voltages VDD and VSS.

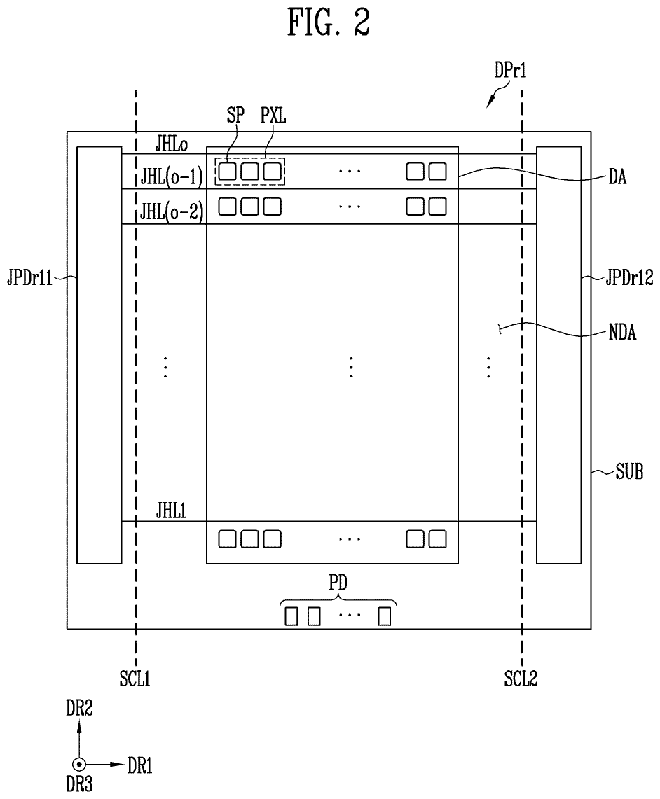

FIG. 2 is a plan view schematically illustrating an embodiment of the display panel of FIG. 1.

Referring to FIG. 2, an embodiment of the display panel 110 depicted in FIG. 1 may include a display area DA and a non-display area NDA. Hereinafter, the embodiment of the display panel 110 shown in FIG. 2 will be referred to as display panel DPr1. The display panel DPr1 may display an image through the display area DA. The non-display area NDA may be disposed outside (e.g., around or adjacent to) the display area DA.

The display panel DPr1 may include a substrate SUB, sub-pixels SP, a first metal pad JPDr11, a second metal pad JPDr12, metal lines JHL1 to JHLo (“o” may be a positive integer greater than one), and pads PD.

In a case that the display panel DPr1 is used as a display screen for a head-mounted display (HMD), a virtual reality (VR) device, a mixed reality (MR) device, an augmented reality (AR) device, or the like, the display panel DPr1 may be positioned relatively close to the eyes of a user. Relatively high-density sub-pixels SP may be used to improve a quality of an image presented to the user. To increase the pixel density of the sub-pixels SP, the substrate SUB may be provided as a silicon substrate. The sub-pixels SP and/or the display panel DPr1 may be formed on the substrate SUB that is a silicon substrate. The display device 100 (refer to FIG. 1) including the display panel DPr1 formed on the substrate SUB that is a silicon substrate may be referred to as an organic light emitting diode (OLED) on Silicon (OLEDoS) display device.

The sub-pixels SP may be disposed in the display area DA on the substrate SUB. The sub-pixels SP may be arranged in the form of a matrix along a first direction DR1 and a second direction DR2 transverse to the first direction DR1. However, embodiments are not limited to the aforementioned example. For example, the sub-pixels SP may be arranged in a zigzag pattern in the first direction DR1 and the second direction DR2. For example, the sub-pixels SP may be arranged in the form of a Pentile™ arrangement. The first direction DR1 may refer to a row direction, and the second direction DR2 may refer to a column direction. Two or more sub-pixels among the sub-pixels SP may form one (or a) pixel PXL.

The substrate SUB may include a display area DA and a non-display area NDA. Components for controlling the sub-pixels SP may be disposed in the non-display area NDA on the substrate SUB. For example, electrically connected to the sub-pixels SP, lines such as the first to m-th gate lines GL1 to GLm and the first to n-th data lines DL1 to DLn of FIG. 1 may be spatially disposed in the non-display area NDA and may extend into the display area DA.

The first metal pad JPDr11 may be positioned in the non-display area NDA. The first metal pad JPDr11 may have an approximately rectangular shape with long sides extending in the second direction DR2 and short sides extending in the first direction DR1 in a view in the third direction DR3. A length of the long sides may be similar to a length of the display area DA in the second direction DR2. The first metal pad JPDr11 may include at least one metal material. For example, the first metal pad JPDr11 may include a material having relatively high resistivity and melting point, such as at least one of molybdenum (Mo), titanium (Ti), and titanium nitride (TiN). The first metal pad JPDr11 may be positioned in a direction opposite to the first direction DR1 from the display area DA. For instance, the first metal pad JPDr11 may be spaced apart from the display area DA in a direction opposite the first direction DR1.

The second metal pad JPDr12 may be positioned in the non-display area NDA, and may be positioned in the first direction DR1 from the first metal pad JPDr11. For instance, the second metal pad JPDr12 may be spaced part from the first metal pad JPDr11 in the first direction DR1. The second metal pad JPDr12 may have an approximately rectangular shape with long sides extending in the second direction DR2 and short sides extending in the first direction DR1 in a view in the third direction DR3. A length of the long sides may be similar to the length of the display area DA in the second direction DR2. The second metal pad JPDr12 may include at least one metal material. For example, the second metal pad JPDr12 may include a material having relatively high resistivity and melting point, such as at least one of molybdenum (Mo), titanium (Ti), and titanium nitride (TiN). The second metal pad JPDr12 may be positioned in the first direction DR1 from the display area DA. For instance, the second metal pad JPDr12 may be spaced apart from the display area DA in the first direction DR1.

The metal lines JHL1 to JHLo may electrically connect the first metal pad JPDr11 to the second metal pad JPDr12. Here, “o” is an integer greater than 1. Each of the metal lines JHL1 to JHLo may extend in the first direction DR1 so as not to overlap the sub-pixels SP in a view in the third direction DR3. Not overlapping the sub-pixels SP refers to not overlapping the light emission areas of the sub-pixels SP in the third direction DR3. The metal lines JHL1 to JHLo may extend to be spaced apart from the light emission areas of the sub-pixels SP in a view in the third direction DR3. The metal lines JHL1 to JHLo may be arranged parallel (or substantially parallel) to each other in the second direction DR2. First ends of the metal lines JHL1 to JHLo may be electrically connected to the first metal pad JPDr11. Second ends of the metal lines JHL1 to JHLo may be electrically connected to the second metal pad JPDr12. For example, the metal lines JHL1 to JHLo may include a material having relatively high resistivity and melting point, such as at least one of molybdenum (Mo), titanium (Ti), and titanium nitride (TiN). The metal lines JHL1 to JHLo, the first metal pad JPDr11, and the second metal pad JPDr12 may be formed at a same time through one or more same process, or may be formed at different time points through different processes. In some implementations, the metal lines JHL1 to JHLo, the first metal pad JPDr11, and the second metal pad JPDr12 may be part of a same layer.

In a case that a first voltage is applied to the first metal pad JPDr11 and a second voltage different from the first voltage is applied to the second metal pad JPDr12, heat may be generated in the metal lines JHL1 to JHLo due to Joule heating. The first voltage may be formed of a single pulse, or may include multiple pulses. Due to the heat generation, organic material adjacent to the metal lines JHL1 to JHLo may sublimate. For example, the second voltage may be a relatively low voltage or ground voltage.

An imaginary (or virtual) first section line SCL1 may extend in the second direction DR2 between the first metal pad JPDr11 and the display area DA. The first section line SCL1 may cross (or intersect) the metal lines JHL1 to JHLo. An imaginary (or virtual) second section line SCL2 may extend in the second direction DR2 between the second metal pad JPDr12 and the display area DA. The second section line SCL2 may cross (or intersect) the metal lines JHL1 to JHLo.

After or as part of the Joule heating process, the display panel DPr1 may be cut along the first and second section lines SCL1 and SCL2 so that the first metal pad JPDr11 and the second metal pad JPDr12 may not be present in a final product, e.g., a final product of the display device 100. In an embodiment, the display panel DPr1 may not be cut along the first and second section lines SCL1 and SCL2 so that the first metal pad JPDr11 and the second metal pad JPDr12 may be present in a final product.

At least one of the gate driver 120, the data driver 130, the voltage generator 140, the controller 150, and the temperature sensor 160 of FIG. 1 may be integrated in (or as part of) the non-display area NDA of the display panel DPr1. In embodiments, the gate driver 120 of FIG. 1 may be mounted on the display panel DPr1 and positioned in the non-display area NDA. In some embodiments, the gate driver 120 may be implemented as an integrated circuit that is separate from the display panel DPr1. In embodiments, the temperature sensor 160 may be positioned in the non-display area NDA to sense the temperature of the display panel DPr1.

The pads PD may be disposed in the non-display area NDA on the substrate SUB. The pads PD may be electrically connected to the sub-pixels SP through lines. For example, the pads PD may be electrically connected to the sub-pixels SP through the first to n-th data lines DL1 to DLn.

The pads PD may provide an interface to the display panel DPr1 for other components of the display device 100 (refer to FIG. 1). In embodiments, voltages and signals for the operation of the components included in (or as part of) the display panel DPr1 may be provided through the pads PD from the driver integrated circuit DIC of FIG. 1. For example, the first to n-th data lines DL1 to DLn may be connected to the driver integrated circuit DIC through the pads PD. For example, the first and second power voltages VDD and VSS may be received from the driver integrated circuit DIC through the pads PD. For example, in a case that the gate driver 120 is mounted on the display panel DPr1, the gate control signal GCS may be transmitted from the driver integrated circuit DIC to the gate driver 120 through the pads PD.

In embodiments, a circuit board may be electrically connected to the pads PD by, for instance, a conductive adhesive component, such as an anisotropic conductive film. The circuit board may be a flexible circuit board or flexible film that is made of flexible material, but embodiments are not limited to these examples. The driver integrated circuit DIC may be mounted on the circuit board and be electrically connected to the pads PD.

In embodiments, the display area DA may have various shapes in a view in the third direction DR3. The display area DA may have a closed-loop shape in a view in the third direction DR3, including linear and/or curved sides. For example, the display area DA may have one or more shapes, such as polygons, circles, semicircles, ellipses, and/or the like, in a view in the third direction DR3.

In embodiments, the display panel DPr1 may have a planar display surface. In embodiments, the display panel DPr1 may have a display surface that is at least partially rounded or curved. In embodiments, the display panel DPr1 may be flexible, for example, bendable, foldable, rollable, and/or twistable. The display panel DPr1 and/or the substrate SUB may include materials having flexible properties.

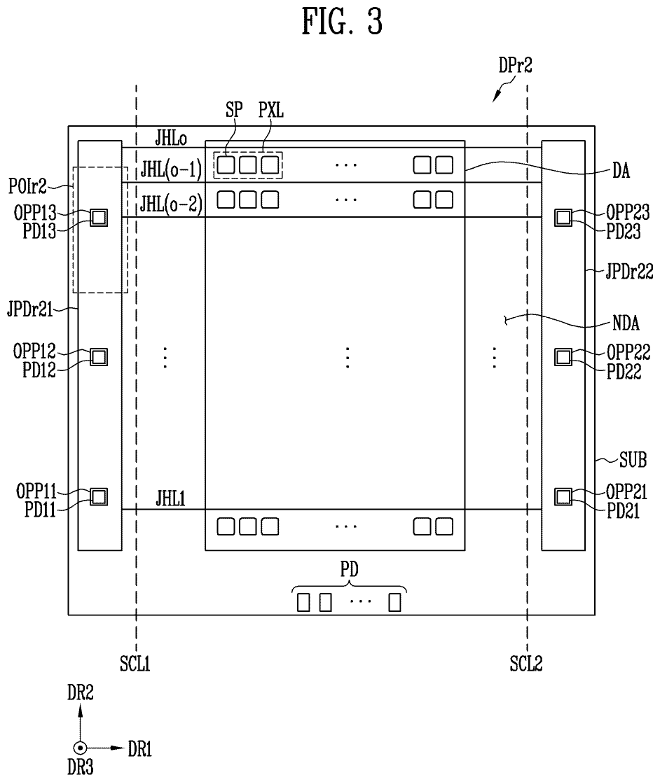

Characteristics of the display panel DPr1 described with reference to FIG. 2 may be applied to embodiments to be described with reference to FIGS. 3, 7, and 10. Hereinafter, repetitive explanations will be omitted.

FIG. 3 is a plan view schematically illustrating an embodiment of the display panel of FIG. 1.

A display panel DPr2 depicted in FIG. 3 may include a first metal pad JPDr21 and a second metal pad JPDr22.

The first metal pad JPDr21 may include openings OPP11, OPP12, and OPP13. In some embodiments, the openings OPP11, OPP12, and OPP13 may be spaced apart from one another along the second direction DR2. Additional pads PD11, PD12, and PD13 may be respectively exposed through the openings OPP11, OPP12, and OPP13.

The second metal pad JPDr22 may include openings OPP21, OPP22, and OPP23. In some embodiments, the openings OPP21, OPP22, and OPP23 may be spaced apart from one another along the second direction DR2. Additional pads PD21, PD22, and PD23 may be respectively exposed through the openings OPP21, OPP22, and OPP23.

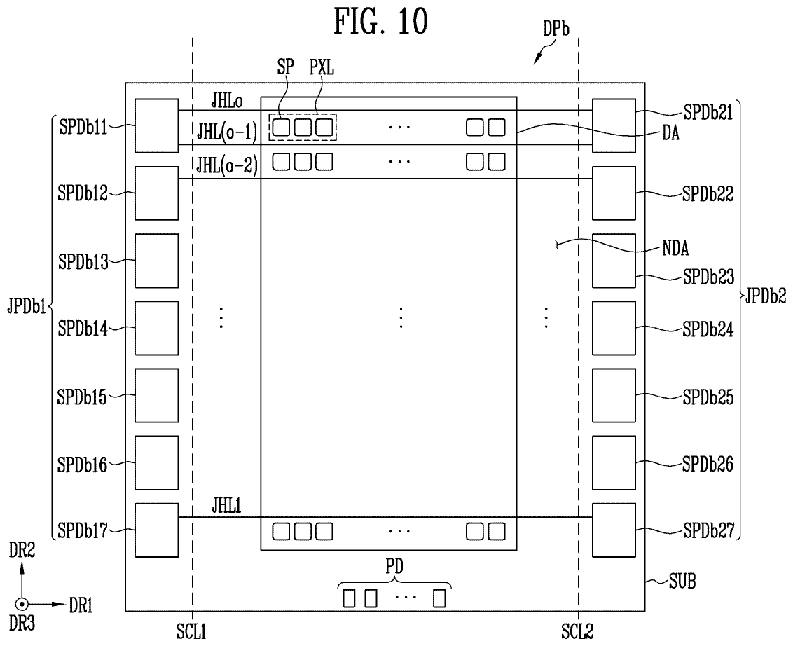

As described above, during a Joule heating process, a first voltage may be applied to the first metal pad JPDr21, and a second voltage may be applied to the second metal pad JPDr22. The second power voltage VSS may be applied to the additional pads PD11, PD12, PD13, PD21, PD22, and PD23. The second power voltage VSS may be a voltage applied in common to cathode electrodes CE of the sub-pixels SP (refer to FIG. 12).

For example, a process of fabricating the display device 100 may include setting a voltage level of the second power voltage VSS to allow the sub-pixels SP to emit light at desired (or selectable) luminance. The additional pads PD11 to PD23 may be test pads for testing a voltage level of the second power voltage VSS. The display panel DPr2 may be cut along the first and second section lines SCL1 and SCL2 so that the first metal pad JPDr21, the second metal pad JPDr22, and the additional pads PD11 to PD23 may not be present in a final product.

In some implementations, the display panel DPr2 may not be cut along the first and second section lines SCL1 and SCL2. The first metal pad JPDr21, the second metal pad JPDr22, and the additional pads PD11 to PD23 may remain in the final product. During use of the display device 100 by a user, the second power voltage VSS may be supplied through the additional pads PD11, PD12, PD13, PD21, PD22, and PD23.

In an embodiment, other types of voltage, instead of (or in addition to) the second power voltage VSS, may be applied to the additional pads PD11, PD12, PD13, PD21, PD22, and PD23. Whatever the case, the aforementioned details pertaining to the first and second section lines SCL1 and SCL2 may be applied.

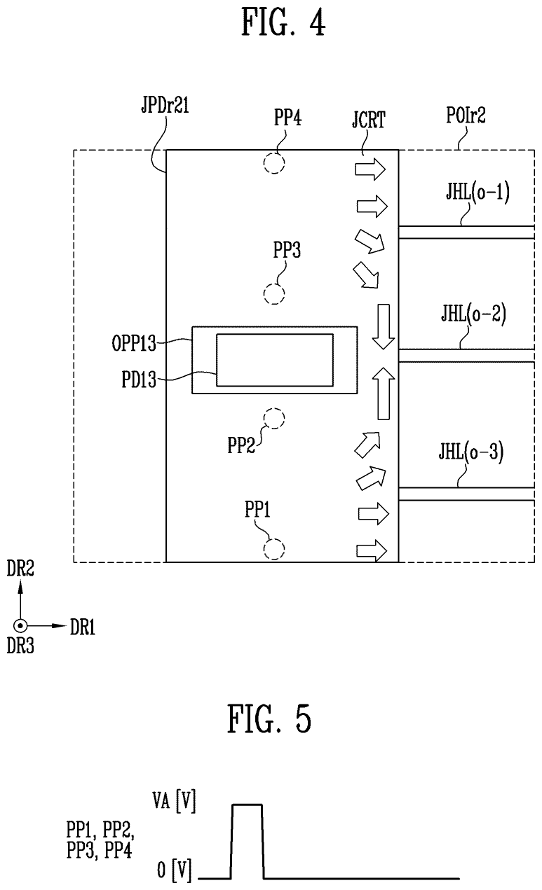

FIGS. 4 to 6 are schematic diagrams for describing a Joule heating process in a method of fabricating the display panel of FIG. 3 according to an embodiment.

Referring to FIG. 4, there is provided a schematic plan view showing an enlargement of a partial area POIr2 of FIG. 3 according to an embodiment. The first metal pad JPDr21 may include pin areas, such as pin areas PP1, PP2, PP3, and PP4. Hereinafter, the pin areas will be referred to as pin areas PP1, PP2, PP3, and PP4, but embodiments are not limited to four pin areas. The pin areas PP1, PP2, PP3, and PP4 may be areas that contact (e.g., physically and electrically) pins provided to apply the first voltage.

The first voltage may be applied to each of the pin areas PP1, PP2, PP3, and PP4. Referring to FIG. 5, the first voltage may be a voltage pulse having a first voltage level VA. For reference, pin areas PP1, PP2, PP3, and PP4 may be formed in (or as part of) the first metal pad JPDr11 of the display panel DPr1 of FIG. 2. The first voltage applied to the pin areas PP1, PP2, PP3, and PP4 formed in the first metal pad JPDr11 may be equivalent to the voltage pulse having the first voltage level VA of FIG. 5.

Currents JCRT supplied from the pin areas PP1, PP2, PP3, and PP4 may flow unevenly due to the presence of the openings, such as opening OPP13 (refer to FIG. 4). A relatively high current may flow through the metal line JHL(o-2) positioned in the first direction DR1 from the additional pad PD13.

Referring to FIG. 6, there is illustrated a graph schematically showing an amount of current flowing through the metal lines JHL1 to JHLo based on the positions of the pixel rows. The pixels PXL included in a same pixel row may be electrically connected to a same gate line among gate lines GL1 to GLm. The pixels PXL included in a same pixel row may be arranged in (e.g., spaced apart from one another along) the first direction DR1.

It may be observed that relatively large current flows through metal lines adjacent to the additional pads PD11, PD12, and PD13. In a case that amounts of current flowing through the metal lines JHL1 to JHLo differ from each other, amounts of heat generated in the metal lines JHL1 to JHLo may also differ from each other. Undesirable uneven sublimation of the organic material may be caused by different amounts of heat being generated in the metal lines JHL1 to JHLo.

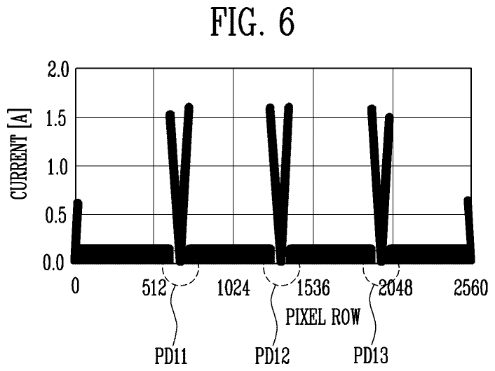

FIG. 7 is a plan view schematically illustrating an embodiment of the display panel of FIG. 1.

The display panel DPa of FIG. 7 is different from the display panel DPr2 of FIG. 3 in that that the display panel DPa of FIG. 7 includes a first metal pad JPDa1 and a second metal pad JPDa2 in accordance with some embodiments.

The first metal pad JPDa1 may include first sub-metal pads SPDa11, SPDa12, SPDa13, SPDa14, SPDa15, SPDa16, and SPDa17. For example, the first sub-metal pads SPDa11, SPDa12, SPDa13, SPDa14, SPDa15, SPDa16, and SPDa17 may be spaced apart from each other in (or along) the second direction DR2. The first sub-metal pads SPDa12, SPDa14, and SPDa16 of a first group may respectively include openings OPP11, OPP12, and OPP13. Additional pads PD11, PD12, and PD13 may be respectively exposed through the openings OPP11, OPP12, and OPP13. The first sub-metal pads SPDa11, SPDa13, SPDa15, and SPDa17 of a second group may not include openings.

The second metal pad JPDa2 may include second sub-metal pads SPDa21, SPDa22, SPDa23, SPDa24, SPDa25, SPDa26, and SPDa27. The second sub-metal pads SPDa21, SPDa22, SPDa23, SPDa24, SPDa25, SPDa26, and SPDa27 may be spaced apart from each other in (or along) the second direction DR2. The second sub-metal pads SPDa22, SPDa24, and SPDa26 of a first group may respectively include openings OPP21, OPP22, and OPP23. Additional pads PD21, PD22, and PD23 may be respectively exposed through the openings OPP21, OPP22, and OPP23. The second sub-metal pads SPDa21, SPDa23, SPDa25, and SPDa27 of a second group may not include openings.

In an embodiment, a width of each of the first sub-metal pads SPDa12, SPDa14, and SPDa16 of the first group in the second direction DR2 may be less than a width of each of the first sub-metal pads SPDa11, SPDa13, SPDa15, and SPDa17 of the second group in the second direction DR2. Similarly, a width of each of the second sub-metal pads SPDa22, SPDa24, and SPDa26 of the first group in the second direction DR2 may be less than a width of each of the second sub-metal pads SPDa21, SPDa23, SPDa25, and SPDa27 of the second group in the second direction DR2.

In an embodiment, a width of each of the first sub-metal pads SPDa12, SPDa14, and SPDa16 of the first group in the first direction DR1 may be equivalent to a width of each of the first sub-metal pads SPDa11, SPDa13, SPDa15, and SPDa17 of the second group in the first direction DR1. Similarly, a width of each of the second sub-metal pads SPDa22, SPDa24, and SPDa26 of the first group in the first direction DR1 may be equivalent to a width of each of the second sub-metal pads SPDa21, SPDa23, SPDa25, and SPDa27 of the second group in the first direction DR1.

Among the metal lines JHL1 to JHLo, some metal lines (such as metal line JHL(o-2)) may connect the second sub-metal pads SPDa22, SPDa24, and SPDa26 of the first group to the first sub-metal pads SPDa12, SPDa14, and SPDa16 of the first group.

Among the metal lines JHL1 to JHLo, some other metal lines (such as metal lines JHL1, JHL(o-1), and JHLo) may connect the second sub-metal pads SPDa21, SPDa23, SPDa25, and SPDa27 of the second group to the first sub-metal pads SPDa11, SPDa13, SPDa15, and SPDa17 of the second group.

The second power voltage VSS may be applied to the additional pads PD11, PD12, PD13, PD21, PD22, and PD23. The second power voltage VSS may be a voltage applied in common to the cathode electrodes CE of the sub-pixels SP (refer to FIG. 12).

For example, a process of fabricating the display device 100 may include setting a voltage level of the second power voltage VSS to allow the sub-pixels SP to emit light at desired (or selectable) luminance. The additional pads PD11, PD12, PD13, PD21, PD22, and PD23 may be test pads for testing a voltage level of the second power voltage VSS. The display panel DPa may be cut along the first and second section lines SCL1 and SCL2 so that the first metal pad JPDa1, the second metal pad JPDa2, and the additional pads PD11, PD12, PD13, PD21, PD22, and PD23 may not be present in a final product.

In some implementations, the display panel DPa may not be cut along the first and second section lines SCL1 and SCL2. The first metal pad JPDa1, the second metal pad JPDa2, and the additional pads PD11 to PD23 may remain in the final product. During use of the display device 100 by a user, the second power voltage VSS may be supplied through the additional pads PD11, PD12, PD13, PD21, PD22, and PD23.

In an embodiment, other types of voltages, instead of (or in addition to) the second power voltage VSS, may be applied to the additional pads PD21, PD22, and PD23. Whatever the case, the aforementioned details pertaining to the first and second section lines SCL1 and SCL2 may be applied.

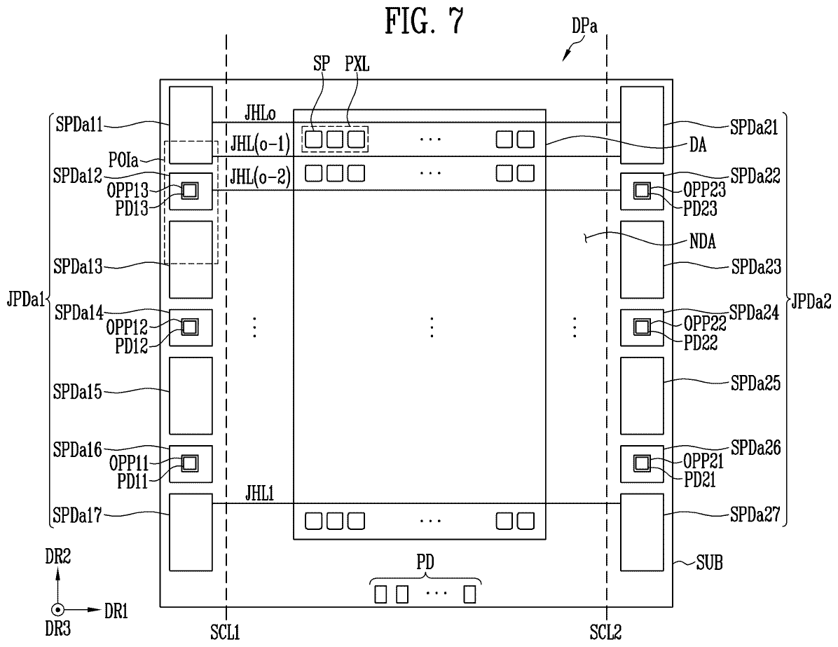

FIGS. 8 and 9 are schematic diagrams for describing a Joule heating process in a method of fabricating the display panel of FIG. 7 according to an embodiment.

Referring to FIG. 8, there is provided a schematic plan view showing an enlargement of a partial area POIa of FIG. 7 according to an embodiment. The first sub-metal pads (such as first sub-metal pads SPDa11, SPDa12, and SPDa13) may include pin areas (such as pin areas PP1, PP2, PP3, and PP4). Hereinafter, the pin areas will be referred to as pin areas PP1, PP2, PP3, and PP4, but the pin areas PP1, PP2, PP3, and PP4 are not limited to four. The pin areas PP1, PP2, PP3, and PP4 may be areas that contact (e.g., physically and/or electrically) pins provided to apply corresponding voltages.

Referring to FIGS. 8 and 9, at least one first voltage pulse may be applied to each of the first sub-metal pads (e.g., sub-metal pad SPDa12) of the first group. For example, at least one first voltage pulse may be applied to each of the pin areas PP2 and PP3 of the first sub-metal pad SPDa12.

At least one second voltage pulse may be applied to each of the first sub-metal pads (such as first sub-metal pads SPDa11 and SPDa13) of the second group. For example, at least one second voltage pulse may be applied to each of the pin areas PP1 and PP4 of the first sub-metal pads SPDa11 and SPDa13.

Voltage levels and numbers of at least one first voltage pulse and at least one second voltage pulse may be set so that a power density of each of the first sub-metal pads SPDa12, SPDa14, and SPDa16 of the first group can be equivalent to a power density of each of the first sub-metal pads SPDa11, SPDa13, SPDa15, and SPDa17 of the second group. Applying power according to the power density may be determined using Equation 1 provided below.

$$AppPower = PowerD * PDvol \qquad Equation 1$$

AppPower may denote applying power, PowerD may denote a power density, and PDvol may denote a volume of the sub-metal pad. The first sub-metal pads SPDa12, SPDa14, and SPDa16 of the first group including the openings OPP11, OPP12, and OPP13 may have a smaller volume per unit volume compared to the first sub-metal pads SPDa11, SPDa13, SPDa15, and SPDa17 of the second group that do not include openings. In a case that the power density PowerD is set to an equivalent value, the applying power for the first sub-metal pads SPDa12, SPDa14, and SPDa16 of the first group may be set to a value lower than the applying power for the first sub-metal pads SPDa11, SPDa13, SPDa15, and SPDa17 of the second group. Applying voltage may be determined using Equation 2 provided below.

$$A p p V = ( A ppPower * LineR ) \hat{} 0.5 \qquad Equation 2$$

AppV may denote an applying voltage, AppPower may denote applying power, and LineR may denote a resistance of each of the metal lines JHL1 to JHLo. The resistances of the metal lines JHL1 to JHLo may be equivalent to each other. A voltage applied to each of the pin areas PP2 and PP3 of the first sub-metal pad SPDa12 of the first group may be lower than that applied to each of the pin areas PP1 and PP4 of the first sub-metal pads SPDa11 and SPDa13 of the second group. For example, a second voltage level VB of at least one first voltage pulse may be set to be lower than a first voltage level VA of at least one second voltage pulse (refer to FIG. 9).

In an embodiment, a number of at least one first voltage pulse may be greater than a number of at least one second voltage pulse. Referring to FIG. 9, a number of first voltage pulses applied to the pin areas PP2 and PP3 may be three. A number of second voltage pulses applied to the pin areas PP1 and PP4 may be one. By time-sharing the application of voltage, the voltage applied to the pin areas PP2 and PP3 may be further reduced.

In accordance with the various embodiments, unlike as described in FIG. 6, it is possible to prevent (or at least mitigate) relatively high current from flowing through the metal lines adjacent to the additional pads PD11, PD12, and PD13, and amounts of heat generated in the metal lines may be adjusted to be uniform. A voltage application device with relatively low specifications may be used, thus leading to a reduction in production cost. In addition, time-sharing of the application of voltage pulses may make it possible to reduce peak current. Using a relatively low voltage may reduce the possibility of generating static electricity.

A third voltage may be applied to the second sub-metal pads SPDa22, SPDa24, and SPDa26 of the first group and the second sub-metal pads SPDa21, SPDa23, SPDa25, and SPDa27 of the second group. A voltage level of the third voltage may be lower than the second voltage level VB of the at least one first voltage pulse and the first voltage level VA of the at least one second voltage pulse. For example, the voltage level of the third voltage may be a ground level voltage or 0 volts. Current may flow from the first sub-metal pads SPDa12, SPDa14, and SPDa16 of the first group to the second sub-metal pads SPDa22, SPDa24, and SPDa26 of the first group through the metal lines (such as metal line JHL(o-2)). Current may flow from the first sub-metal pads SPDa11, SPDa13, SPDa15, and SPDa17 of the second group to the second sub-metal pads SPDa21, SPDa23, SPDa25, and SPDa27 of the second group through the metal lines (such as metal lines JHL1, JHL(o-1), and JHLo).

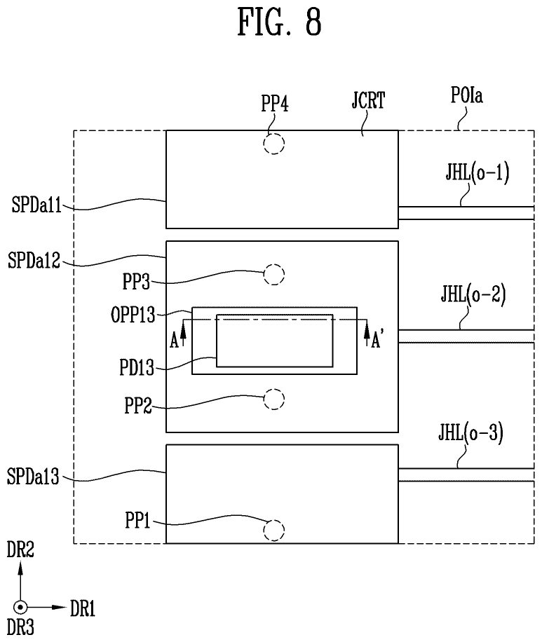

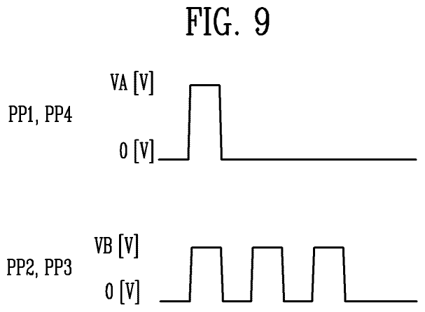

FIG. 10 is a plan view schematically illustrating an embodiment of the display panel of FIG. 1. FIG. 11 is a schematic diagram for describing a Joule heating process in a method of fabricating the display panel of FIG. 10 according to an embodiment.

The display panel DPb of FIG. 10 is different from the display panel DPr1 of FIG. 2 in that that the display panel DPb of FIG. 10 includes a first metal pad JPDb1 and a second metal pad JPDb2 in accordance with some embodiments.

The first metal pad JPDb1 may extend in the second direction DR2. The first metal pad JPDb1 may include first sub-metal pads SPDb11, SPDb12, SPDb13, SPDb14, SPDb15, SPDb16, and SPDb17 spaced apart from each other. For example, the first sub-metal pads SPDb11 to SPDb17 may be arranged in (or along) the second direction DR2. Hereinafter, the first sub-metal pads SPDb11, SPDb12, SPDb13, SPDb14, SPDb15, SPDb16, and SPDb17 may be collectively referred to as first sub-metal pads SPDb11 to SPDb17.

Widths of the first sub-metal pads SPDb11 to SPDb17 in the second direction DR2 may be equivalent to each other. Widths of the first sub-metal pads SPDb11 to SPDb17 in the first direction DR1 may be equivalent to each other. Multiple voltage pulses having an identical voltage level VC may be applied to each of the first sub-metal pads SPDb11 to SPDb17 (refer to FIG. 11). Referring to Equation 1, in a case that volumes of the first sub-metal pads SPDb11 to SPDb17 are equivalent, applying powers AppPower may also be equivalent. According to Equation 2, a voltage having an equivalent voltage level may be applied to each of the first sub-metal pads SPDb11 to SPDb17.

In an embodiment, by time-sharing the application of voltage, the voltage applied to the first sub-metal pads SPDb11 to SPDb17 may be further reduced. A voltage application device with relatively low specifications may be used, thus leading to a reduction in production cost. Time-sharing of the application of voltage pulses may make it possible to reduce peak current. Using a relatively low voltage may reduce the possibility of generating static electricity.

The second metal pad JPDb2 may extend in the second direction DR2. The second metal pad JPDb2 may include second sub-metal pads SPDb21, SPDb22, SPDb23, SPDb24, SPDb25, SPDb26, and SPDb27 spaced apart from each other. For example, the second sub-metal pads SPDb21 to SPDb27 may be arranged in (or along) the second direction DR2. Hereinafter, the second sub-metal pads SPDb21, SPDb22, SPDb23, SPDb24, SPDb25, SPDb26, and SPDb27 may be collectively referred to as second sub-metal pads SPDb21 to SPDb27.

Widths of the second sub-metal pads SPDb21 to SPDb27 in the second direction DR2 may be equivalent to each other. Widths of the second sub-metal pads SPDb21 to SPDb27 in the first direction DR1 may be equivalent to each other.

A voltage with a ground level or 0 volts may be applied to the second sub-metal pads SPDb21 to SPDb27. Current may flow from the first sub-metal pads SPDb11 to SPDb17 to the second sub-metal pads SPDb21 to SPDb27 through the metal lines JHL1 to JHLo.

FIG. 12 is a schematic block diagram for describing a sub-pixel according to an embodiment.

Referring to FIG. 12, there is schematically illustrated a sub-pixel SPij disposed on an i-th row (where “i” is an integer greater than or equal to 1 and less than or equal to m) and a j-th column (where “j” is an integer greater than or equal to 1 and less than or equal to n) among the sub-pixels SP. The sub-pixel SPij may include a sub-pixel circuit SPC and a light-emitting element LD.

The light-emitting element LD may be electrically connected between a first power voltage node VDDN and a second power voltage node VSSN. The first power voltage node VDDN may be a node provided to transmit the first power voltage VDD of FIG. 1. The second power voltage node VSSN may be a node provided to transmit the second power voltage VSS of FIG. 1.

An anode electrode AE of the light-emitting element LD may be electrically connected to the first power voltage node VDDN through the sub-pixel circuit SPC. A cathode electrode CE of the light-emitting element LD may be electrically connected to the second power voltage node VSSN. For example, the anode electrode AE of the light-emitting element LD may be electrically connected to the first power voltage node VDDN through one or more transistors included in (or as part of) the sub-pixel circuit SPC.

The sub-pixel circuit SPC may be electrically connected both to an i-th gate line GLi among the first to m-th gate lines GL1 to GLm of FIG. 1 and to a j-th data line DLj among the first to n-th data lines DL1 to DLn of FIG. 1. The sub-pixel circuit SPC may be configured to control the light-emitting element LD in response to signals received through the aforementioned signal lines, e.g., the i-th gate line GLi and the j-th data line DLj.

The sub-pixel circuit SPC may operate in response to a gate signal received through the i-th gate line GLi. The sub-pixel circuit SPC may receive a data signal through a j-th data line DLj. For example, the sub-pixel circuit SPC may store a voltage corresponding to the data signal in response to the gate signal. Based on the voltage stored in the sub-pixel circuit SPC, the light-emitting element LD may generate light with a luminance corresponding to the data signal.

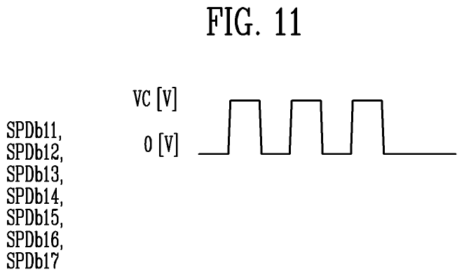

FIG. 13 is a schematic diagram for describing an embodiment of the sub-pixel SPij.

Referring to FIG. 13, the sub-pixel SPij may include a sub-pixel circuit SPC and a light-emitting element LD. The sub-pixel circuit SPC may include first to fourth transistors T1 to T4 and a storage capacitor Cst.

The first transistor T1 may include a gate electrode electrically connected to a first node N1, a first electrode electrically connected to a second node N2, and a second electrode electrically connected to an anode electrode AE of the light-emitting element LD. The first transistor T1 may include sub-transistors T1-1 and T1-2 connected in series with each other. The first transistor T1 may be a driving transistor.

The second transistor T2 may include a gate electrode electrically connected to the i-th gate line GLi, a first electrode electrically connected to the j-th data line DLj, and a second electrode electrically connected to the first node N1.

The third transistor T3 may include a gate electrode electrically connected to the second node N2, a first electrode electrically connected to a first power voltage node VDDN, and a second electrode electrically connected to the second node N2.

The fourth transistor T4 may include a gate electrode and a first electrode that are electrically connected to the anode electrode AE of the light-emitting element LD, and a second electrode configured to receive a reference voltage GND. The reference voltage GND may be set to be less than the first power voltage VDD. In an embodiment, the reference voltage GND may be equivalent to the second power voltage VSS. In an embodiment, the reference voltage GND may be different from the second power voltage VSS.

The storage capacitor Cst may include a first electrode electrically connected to the first power voltage node VDDN, and a second electrode electrically connected to the first node N1.

The light-emitting element LD may include the anode electrode AE, the cathode electrode CE, and an emission structure. The emission structure may be disposed between the anode electrode AE and the cathode electrode CE.

In a case that a gate signal of a turn-on level (e.g., a relatively low level) is applied to the i-th gate line GLi, the second transistor T2 may be turned on. A data signal applied to the j-th data line DLj may be applied to the first node N1 through the second transistor T2. The storage capacitor Cst may maintain a voltage of (or corresponding to) the data signal. In response to the voltage of the data signal, the first transistor T1 may determine (or regulate) an amount of driving current flowing from the first power voltage node VDDN to the second power voltage node VSSN. The light-emitting element LD may emit light at a luminance corresponding to the amount of driving current.

The third transistor T3 and the fourth transistor T4 may be transistors electrically connected in the form of diodes, and may limit the direction of current to prevent (or at least mitigate) current from flowing in a reverse direction. In an embodiment, the third transistor T3 and the fourth transistor T4 may be removed from the sub-pixel circuit SPC. In a case that the third transistor T3 is removed, the second node N2 may be electrically connected (e.g., directly electrically connected) to the first power voltage node VDDN.

The first to fourth transistors T1 to T4 may be P-type transistors. Each of the first to fourth transistors T1 to T4 may be a metal oxide semiconductor field effect transistor (MOSFET). However, embodiments are not limited to the aforementioned examples. For example, at least one of the first to fourth transistors T1 to T4 may be replaced with an N-type transistor.

In embodiments, the first to fourth transistors T1 to T4 may include an amorphous silicon semiconductor, a monocrystalline silicon semiconductor, a polycrystalline silicon semiconductor, an oxide semiconductor, or the like.

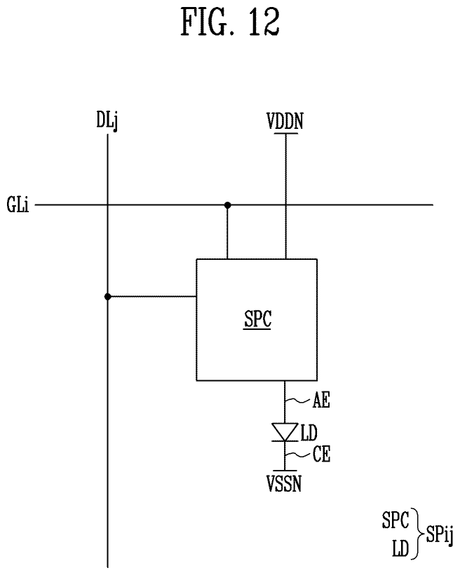

FIG. 14 is an exploded perspective view schematically illustrating a portion of the display panel 110 of FIG. 1 according to an embodiment.

The display panel 110 may include a substrate SUB, a pixel circuit layer PCL, a light-emitting element layer LDL, an encapsulation layer TFE, an optical functional layer OFL, an overcoat layer OC, and a cover window CW.

In embodiments, the substrate SUB may include a silicon wafer substrate formed through a semiconductor process. The substrate SUB may include semiconductor material suitable for forming circuit elements. For example, the semiconductor material may include silicon, germanium, and/or silicon-germanium. The substrate SUB may be provided from a bulk wafer, an epitaxial layer, a silicon on insulator (SOI) layer, a semiconductor on insulator (SeOI) layer, or the like. In embodiments, the substrate SUB may include a glass substrate. In embodiments, the substrate SUB may include a polyimide (PI) substrate.

The pixel circuit layer PCL may be disposed on the substrate SUB. The substrate SUB and/or the pixel circuit layer PCL may include insulating layers, and conductive patterns disposed between the insulating layers. The conductive patterns of the pixel circuit layer PCL may function as at least some of the circuit components, lines, and/or the like of the display panel 110. The conductive patterns may include copper, but embodiments are not limited to copper.

The circuit elements may include respective sub-pixel circuits SPC (refer to FIG. 13) of the first to third sub-pixels SP1, SP2, and SP3. The sub-pixel circuit SPC may include transistors and at least one capacitor. Each transistor may include a semiconductor portion including a source area, a drain area, and a channel area, and a gate electrode overlapping the semiconductor portion. In embodiments, in a case that the substrate SUB is formed of a silicon substrate, the semiconductor portion may be included in (or as part of) the substrate SUB, and the gate electrode may be included in (or as part of) the pixel circuit layer PCL as a conductive pattern of the pixel circuit layer PCL. In an embodiment, in a case that the substrate SUB is formed of a glass substrate or a polyimide (PI) substrate, the semiconductor portion and the gate electrode may be included in (or as part of) the pixel circuit layer PCL. Each capacitor may include electrodes spaced apart from each other. For example, each capacitor may include electrodes spaced apart from each other relative to a plane defined by the first and second directions DR1 and DR2. For example, each capacitor may include electrodes spaced apart from each other in the third direction DR3 with an insulating layer interposed or disposed between the electrodes.

The lines of the pixel circuit layer PCL may include signal lines electrically connected to each of the sub-pixels (such as the first to third sub-pixels SP1, SP2, and SP3), for example, a gate line, an emission control line, and a data line. The lines may further include a line electrically connected to the first power voltage node VDDN of FIG. 13. The lines may further include a line electrically connected to the second power voltage node VSSN of FIG. 13.

The light-emitting element layer LDL may include anode electrodes AE, a pixel defining layer PDL, an emission structure EMS, and a cathode electrode CE.

The anode electrodes AE may be disposed on the pixel circuit layer PCL. The anode electrodes AE may contact (e.g., physically and/or electrically) circuit elements of the pixel circuit layer PCL. The anode electrodes AE may include opaque conductive material configured to reflect light, but embodiments are not limited to this example.

The pixel defining layer PDL may be disposed on the anode electrodes AE. The pixel defining layer PDL may include openings OP that expose respective portions of the anode electrodes AE. The openings OP in the pixel defining layer PDL may be understood as (or at least partially bound) respective light emission areas corresponding to the first to third sub-pixels SP1 to SP3.

In embodiments, the pixel defining layer PDL may include inorganic material. The pixel defining layer PDL may include multiple inorganic layers stacked on top of one another in, for example, the third direction DR3. For example, the pixel defining layer PDL may include at least one of silicon oxide (SiOₓ) and silicon nitride (SiNₓ). In an embodiment, the pixel defining layer PDL may include organic material. However, the material of the pixel defining layer PDL is not limited to the aforementioned examples.

The emission structure EMS may be disposed on the anode electrodes AE exposed through the openings OP in the pixel defining layer PDL. The emission structure EMS may include an emission layer configured to generate light, an electron transport layer configured to transport electrons, and a hole transport layer configured to transport holes.

In embodiments, the emission structure EMS may fill the openings OP in the pixel defining layer PDL and may be disposed on an overall surface of an upper portion of the pixel defining layer PDL. The emission structure EMS may extend over the first to third sub-pixels SP1 to SP3. At least some of the layers in the emission structure EMS may be cut, bent, or removed at boundaries between the sub-pixels. However, embodiments are not limited to the aforementioned example. For instance, portions of the emission structure EMS corresponding to the sub-pixels may be separate from each other, and each may be disposed in (or at least overlap in the third direction DR3) the corresponding opening OP in the pixel defining layer PDL.

The cathode electrode CE may be disposed on the emission structure EMS. The cathode electrode CE may extend over the sub-pixels SP, such as first to third sub-pixels SP1 to SP3. The cathode electrode CE may be provided as a common electrode for the sub-pixels SP.

The cathode electrode CE may be a thin-film metal layer having a thickness allowing light emitted from the emission structure EMS to pass therethrough. The cathode electrode CE may be made of a metal material having a relatively small thickness and/or a transparent conductive material. In embodiments, the cathode electrode CE may include at least one of various transparent conductive materials including at least one of indium tin oxide, indium zinc oxide, indium tin zinc oxide, aluminum zinc oxide, gallium zinc oxide, zinc tin oxide, and gallium tin oxide. In embodiments, the cathode electrode CE may include at least one of silver (Ag) and magnesium (Mg), and/or a compound of silver and/or magnesium. However, the material of the cathode electrode CE is not limited to the foregoing examples.

Any one of the anode electrodes AE, a portion of the emission structure EMS that overlap the any one anode electrode AE, and a portion of the cathode electrode CE that overlaps the portion of the emission structure EMS can be understood as constituting one (or a) light-emitting element LD (refer to FIG. 13). Each of the light-emitting elements LD of the sub-pixels SP may include an anode electrode AE, a portion of the emission structure EMS that overlaps the anode electrode AE, and a portion of the cathode electrode CE that overlaps the portion of the emission structure EMS. In each of the first to third sub-pixels SP1 to SP3, holes injected from the anode electrode AE and electrons injected from the cathode electrode CE may be transported into the emission layer of the emission structure EMS, thus forming excitons. In a case that the excitons make a transition from an excited state to a ground state, light can be generated. Depending on an amount of current flowing through the emission layer EMS, a luminance of light may be determined or regulated. Depending on a configuration of the emission layer EMS, a wavelength or range of wavelengths of light generated by a light-emitting element LD may be determined or selected.

The encapsulation layer TFE may be disposed on the cathode electrode CE. The encapsulation layer TFE may cover (or overlap in the third direction DR3) the light-emitting element layer LDL and/or the pixel circuit layer PCL. The encapsulation layer TFE may be configured to prevent (or mitigate) oxygen and/or water or the like from penetrating into the light-emitting element layer LDL. In embodiments, the encapsulation layer TFE may include a structure formed by alternately stacking one or more inorganic layers and one or more organic layers. For example, the inorganic layer may include at least one of silicon nitride, silicon oxide, silicon oxynitride (SiOₓN_{y}), and the like. For example, the organic layer may include organic insulating material, such as at least one of acrylic resin, epoxy resin, phenol resin, polyamide resin, polyimide resin, unsaturated polyester resin, polyphenylene ether resin, polyphenylene sulfide resin, and benzocyclobutene (BCB). However, the materials of the organic layer and the inorganic layer of the encapsulation layer TFE are not limited to the aforementioned examples.

The encapsulation layer TFE may further include a thin film, such as a thin film of aluminum oxide (AlOₓ), to enhance the encapsulation efficiency of the encapsulation layer TFE. The thin film including aluminum oxide may be positioned on an upper surface of the encapsulation layer TFE that faces the optical functional layer OFL in the third direction DR3 and/or under a lower surface of the encapsulation layer TFE that faces the light-emitting element layer LDL in a direction opposite the third direction DR3.

The thin film including aluminum oxide may be formed through an atomic layer deposition (ALD) method. However, embodiments are not limited to the aforementioned example. The encapsulation layer TFE may further include a thin film formed of at least one of various materials suitable for enhancing the encapsulation efficiency of the encapsulation layer TFE.

The optical functional layer OFL may be disposed on the encapsulation layer TFE. The optical functional layer OFL may include a color filter layer CFL and a lens array LA.

The color filter layer CFL may be disposed between the encapsulation layer TFE and the lens array LA. The color filter layer CFL may be configured to filter light emitted from the emission structure EMS to selectively output light in a wavelength range or color corresponding to each sub-pixel SP. The color filter layer CFL may include color filters CF respectively corresponding to the sub-pixels SP. Each of the color filters CF allows light in a wavelength range corresponding to the related sub-pixel SP to pass through a corresponding color filter CF associated with the related sub-pixel SP. For example, the color filter CF that corresponds to the first sub-pixel SP1 may allow light in a red color to pass through that color filter CF, the color filter CF that corresponds to the second sub-pixel SP2 may allow light in a green color to pass through that color filter CF, and the color filter that corresponds to the third sub-pixel SP3 may allow light in a blue color to pass through that color filter CF. Depending on the light emitted from the emission structure EMS of each sub-pixel SP, at least some of the color filters CF may be omitted.

The lens array LA may be disposed on the color filter layer CFL. The lens array LA may include lenses LS respectively corresponding to the sub-pixels SP. Each of the lenses LS may output and direct light emitted from the emission structure EMS along an intended path, thus enhancing the light output efficiency. The lens array LA may have a relatively high refractive index. For example, the lens array LA may have a higher refractive index than the overcoat layer OC. In embodiments, the lenses LS may include organic material. In embodiments, the lenses LS may include acrylic material. However, the material of the lenses LS is not limited to the foregoing example.

In embodiments, compared to the openings OP of the pixel defining layer PDL, at least some of the color filters CF of the color filter layer CFL and at least some of the lenses LS of the lens array LA may be shifted in a direction of a plane parallel (or substantially parallel) to a plane defined by the first and second directions DR1 and DR2. The aforementioned direction may be referred to as a plane direction. For instance, in a central area of the display area DA, a center of each color filter CF and a center of each lens LS may be axially aligned or overlapped with a center of the corresponding opening OP of the pixel defining layer PDL. For example, in a central area of the display area DA, each opening OP of the pixel defining layer PDL may completely overlap the corresponding color filter CF of the color filter layer CFL and the corresponding lens LS of the lens array LA. In an area of the display area DA that is adjacent to the non-display area NDA, a center of the color filter CF and a center of the lens LS may be shifted in a direction included in a plane parallel to the DR1-DR2 plane from a center of the corresponding opening OP of the pixel defining layer PDL in a view in the third direction DR3, e.g., a center of the color filter CF and a center of the lens LS may be axially offset from one another. For example, in an area adjacent to the non-display area NDA in the display area DA, each opening OP of the pixel defining layer PDL may partially overlap the corresponding color filter CF of the color filter layer CFL and the corresponding lens LS of the lens array LA. Light emitted from the emission structure EMS in a central portion of the display area DA may be efficiently output in a direction normal to a display surface. Light emitted from the emission structure EMS around the perimeter of the display area DA may be efficiently output in a direction inclined at an angle with respect to the direction normal to the display surface.

The overcoat layer OC may be disposed on the lens array LA. The overcoat layer OC may cover (or at least overlap in the third direction DR3) the optical functional layer OFL, the encapsulation layer TFE, the emission structure EMS, and/or the pixel circuit layer PCL. The overcoat layer OC may include various materials suitable for protecting underlying layers from foreign substances, such as dust, water, and/or the like. For example, the overcoat layer OC may include at least one of an inorganic insulating layer and an organic insulating layer. For example, the overcoat layer OC may include epoxy, but it is not limited to epoxy. The overcoat layer OC may have a lower refractive index than the lens array LA.

The cover window CW may be disposed on the overcoat layer OC. The cover window CW may be configured to protect underlying layers. The cover window CW may have a higher refractive index than the overcoat layer OC. The cover window CW may include glass, but embodiments are not limited to glass. For example, the cover window CW may be an encapsulation glass layer configured to protect components disposed thereunder. In some embodiments, the cover window CW may be omitted.

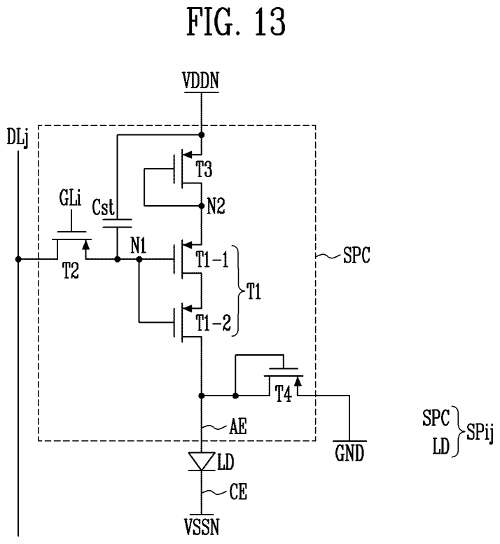

FIG. 15 is a schematic plan view for describing a relationship between sub-pixels and metal lines according to an embodiment.

Referring to FIG. 15, there is schematically illustrated the first to third sub-pixels SP1, SP2, and SP3 sequentially arranged in the first direction DR1. The first sub-pixel SP1 may include a first emission area EMA1 and a non-emission area NEA formed around the first emission area EMA1 in a view in the third direction DR3. The second sub-pixel SP2 may include a second emission area EMA2 and a non-emission area NEA formed around the second emission area EMA2 in a view in the third direction DR3. The third sub-pixel SP3 may include a third emission area EMA3 and a non-emission area NEA formed around the third emission area EMA3 in a view in the third direction DR3.

The first emission area EMA1 may be an area where light is emitted from a portion of the emission structure EMS (refer to FIG. 14) that corresponds to the first sub-pixel SP1. The second emission area EMA2 may be an area where light is emitted from a portion of the emission structure EMS that corresponds to the second sub-pixel SP2. The third emission area EMA3 may be an area where light is emitted from a portion of the emission structure EMS that corresponds to the third sub-pixel SP3. As described with reference to FIG. 14, each emission area may be understood as (or may correspond to) the opening OP of the pixel defining layer PDL corresponding to each of the first to third sub-pixels SP1 to SP3.

Although in FIG. 15 each of the first to third emission areas EMA1, EMA2, and EMA3 are shown having a hexagonal shape in a view in the third direction DR3, the first to third emission areas EMA1, EMA2, and EMA3 may be formed having other shapes including a rectangular shape in a view in the third direction DR3. The first to third emission areas EMA1, EMA2, and EMA3 may be formed in a circular shape, an elliptical shape, or an oval shape in a view in the third direction DR3. Shapes and surface areas of different ones of the first to third emission areas EMA1, EMA2, and EMA3 may be identical to or different from each other.

The metal lines JHLk and JHL(k+1) may generally extend in the first direction DR1, and may have shapes that enclose (or at least partially bound) the corresponding ones of the first to third emission areas EMA1, EMA2, and EMA3. For example, the metal lines JHLk and JHL(k+1) may generally extend in the first direction DR1 and, for instance, may extend in (or with) corresponding zigzag patterns, which may be about 180° out of phase with one another. The metal lines JHLk and JHL(k+1) may be formed in various shapes, such as at least one of a polygonal shape, a circular shape, an elliptical shape, an oval shape in a view in the third direction DR3, corresponding to various shapes of the first to third emission areas EMA1, EMA2, and EMA3 in a view in the third direction DR3.

At least because the metal lines JHLk and JHL(k+1) are not connected to each other in the display area DA, areas POI1 and POI2 that are not covered with the metal lines JHLk and JHL(k+1) may be present between adjacent emission areas among the first to third emission areas EMA1, EMA2, and EMA3. In the areas POI1 and POI2, two or more metal lines JHLk and JHL(k+1) may be disposed adjacent to each other with a relatively small distance between the two or more metal lines JHLk and JHL(k+1). In an embodiment, organic materials provided in the areas POI1 and POI2 that do not overlap the metal lines JHLk and JHL(k+1) may sublimate due to heat generated from the two adjacent metal lines JHLk and JHL(k+1) as previously described, and current leakage through the organic materials can be prevented or at least mitigated.

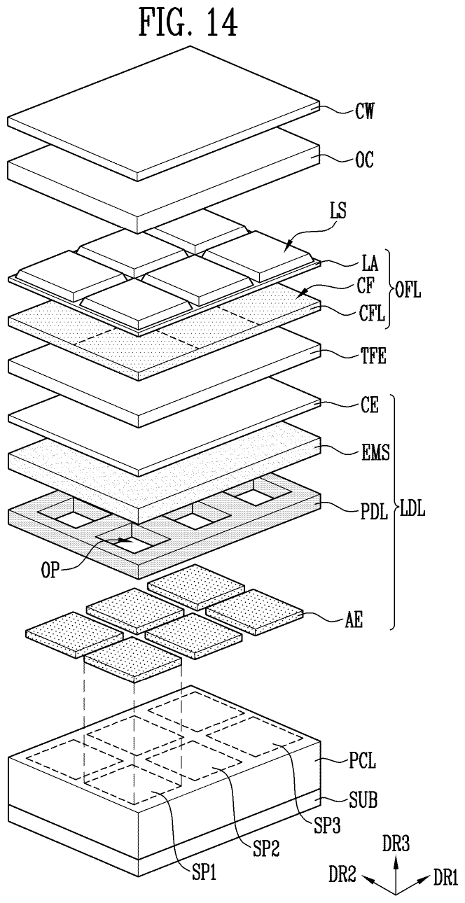

FIG. 16 is a sectional view schematically illustrating an embodiment of the emission structure EMS.

Referring to FIG. 16, an emission structure EMS may have a tandem structure in which first and second emission components EU1 and EU2 are stacked on one another.

Each of the first and second emission components EU1 and EU2 may include an emission layer configured to generate light in response to current applied to the emission layer. The first emission component EU1 may include a first emission layer EML1, a first electron transport component ETU1, and a first hole transport component HTU1. The first emission layer EML1 may be disposed between the first electron transport component ETU1 and the first hole transport component HTU1. The second emission component EU2 may include a second emission layer EML2, a second electron transport component ETU2, and a second hole transport component HTU2. The second emission layer EML2 may be disposed between the second electron transport component ETU2 and the second hole transport component HTU2.

Each of the first and second hole transport components HTU1 and HTU2 may include at least one of a hole injection layer and a hole transport layer, and may further include a hole buffer layer, an electron blocking layer, and/or the like, as desired. The first and second hole transport components HTU1 and HTU2 may have a same configuration or may have different configurations.

Each of the first and second electron transport components ETU1 and ETU2 may include at least one of an electron injection layer and an electron transport layer, and may further include an electron buffer layer, a hole blocking layer, and/or the like, as desired. The first and second electron transport components ETU1 and ETU2 may have a same configuration or have different configurations.

A connection layer, which may be provided in the form of a charge generation layer CGL, may be disposed between the first emission component EU1 and the second emission component EU2 to electrically connect the first and second emission components EU1 and EU2 to each other. In embodiments, the charge generation layer CGL may have a stacked structure including a p-dopant layer and an n-dopant layer. For example, the p-dopant layer may include a p-type dopant, such as at least one of HAT-CN, TCNQ, and NDP-9, and the n-dopant layer may include at least one of an alkali metal, alkaline earth metal, lanthanide metal, and/or a combination of these materials. However, embodiments are not limited to the aforementioned examples.

In embodiments, the first emission layer EML1 and the second emission layer EML2 may generate light of different colors. The light emitted from the first emission layer EML1 and the second emission layer EML2 may be mixed to be visible as white light. For instance, the first emission layer EML1 may generate light of a blue color, and the second emission layer EML2 may generate light of a yellow color. In embodiments, the second emission layer EML2 may include a stacked structure including a first sub-emission layer configured to generate light of a red color, and a second sub-emission layer configured to generate light of a green color. Light of a red color and light of a green color may be mixed to provide light of a yellow color. An intermediate layer configured to perform functions of transporting holes and/or blocking the transport of electrons may be further disposed between the first and second sub-emission layers.

In embodiments, the first emission layer EML1 and the second emission layer EML2 may generate light of a same color.

In embodiments, the emission structure EMS may be formed through a scheme, such as vacuum deposition, inkjet printing, or the like, but embodiments are not limited to these examples.

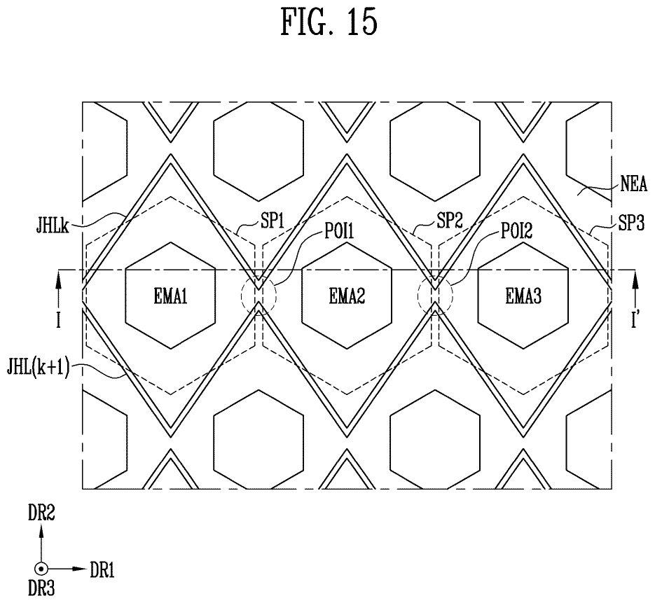

FIG. 17 is a sectional view schematically illustrating an embodiment of the emission structure.

Referring to FIG. 17, an emission structure EMS′ may have a tandem structure in which first to third emission components EU1′ to EU3′ are stacked on one another.

Each of the first to third emission components EU1′ to EU3′ may include an emission layer configured to generate light in response to current applied to the emission layer. The first emission component EU1′ may include a first emission layer EML1′, a first electron transport component ETU1′, and a first hole transport component HTU1′. The first emission layer EML1′ may be disposed between the first electron transport component ETU1′ and the first hole transport component HTU1′. The second emission component EU2′ may include a second emission layer EML2′, a second electron transport component ETU2′, and a second hole transport component HTU2′. The second emission layer EML2′ may be disposed between the second electron transport component ETU2′ and the second hole transport component HTU2′. The third emission component EU3′ may include a third emission layer EML3′, a third electron transport component ETU3′, and a third hole transport component HTU3′. The third emission layer EML3′ may be disposed between the third electron transport component ETU3′ and the third hole transport component HTU3′.

Each of the first to third hole transport components HTU1′ to HTU3′ may include at least one of a hole injection layer and a hole transport layer, and may further include a hole buffer layer, an electron blocking layer, and/or the like, as desired. The first to third hole transport components HTU1′ to HTU3′ may have a same configuration or may have different configurations.

Each of the first to third electron transport components ETU1′ to ETU3′ may include at least one of an electron injection layer and an electron transport layer, and may further include an electron buffer layer, a hole blocking layer, and/or the like, as desired. The first to third electron transport components ETU1′ to ETU3′ may have a same configuration or may have different configurations.

A first charge generation layer CGL1′ may be disposed between the first emission component EU1′ and the second emission component EU2′. A second charge generation layer CGL2′ may be disposed between the second emission component EU2′ and the third emission component EU3′.

In embodiments, the first to third emission layers EML1′ to EML3′ may generate light of different colors from one another. Light emitted from the first to third emission layers EML1′ to EML3′ may be mixed to be visible as white light. For example, the first emission layer EML1′ may generate light of a blue color, the second emission layer EML2′ may generate light of a green color, and the third emission layer EML3′ may generate light of a red color.

In embodiments, two or more emission layers among the first to third emission layers EML1′ to EML3′ may generate light of a same color.

Unlike as described in association with FIGS. 16 and 17, each emission structure EMS of each sub-pixel SP may include a single emission component. The emission components included in adjacent and different sub-pixels SP, such as sub-pixels SP1, SP2, and SP3, may be configured to emit different colors of light from one another. For example, the emission component of the first sub-pixel SP1 may emit light of a red color, the emission component of the second sub-pixel SP2 may emit light of a green color, and the emission component of the third sub-pixel SP3 may emit light of a blue color. The emission components of the first to third sub-pixels SP1 to SP3 may be separate from each other, and each may be disposed in a corresponding opening OP of the pixel defining layer PDL. At least some of the first to third color filters CF1 to CF3 may be omitted.

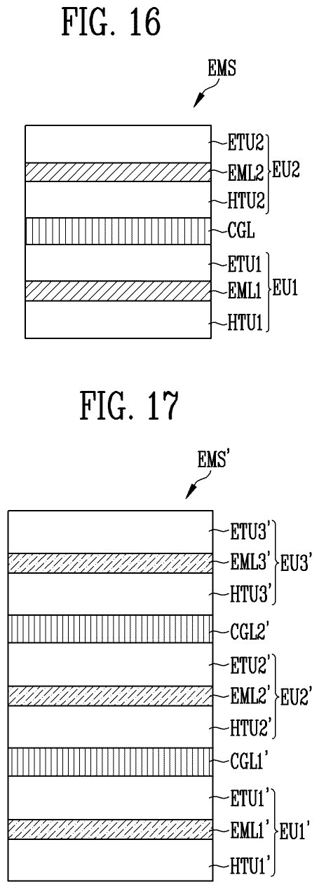

FIG. 18 is a schematic sectional view taken along sectional line I-I′ of FIG. 15 according to an embodiment.

Referring to FIG. 18, there are provided the substrate SUB and the pixel circuit layer PCL disposed on the substrate SUB.

The substrate SUB may include a silicon wafer substrate formed through a semiconductor process. For example, the substrate SUB may include silicon, germanium, and/or silicon-germanium.

The pixel circuit layer PCL may be disposed on the substrate SUB. The substrate SUB and the pixel circuit layer PCL may include respective circuit elements of the first to third sub-pixels SP1 to SP3. For example, the substrate SUB and the pixel circuit layer PCL may include a transistor T_SP1 of the first sub-pixel SP1, a transistor T_SP2 of the second sub-pixel SP2, and a transistor T_SP3 of the third sub-pixel SP3. The transistor T_SP1 of the first sub-pixel SP1 may be any one of the transistors included in the sub-pixel circuit SPC (refer to FIG. 13) of the first sub-pixel SP1. The transistor T_SP2 of the second sub-pixel SP2 may be any one of the transistors included in the sub-pixel circuit SPC of the second sub-pixel SP2. The transistor T_SP3 of the third sub-pixel SP3 may be any one of the transistors included in the sub-pixel circuit SPC of the third sub-pixel SP3. In FIG. 18, one of the transistors of each sub-pixel SP is illustrated for the sake of clear and concise explanation, and the remaining circuit elements of the sub-pixel circuits SPC are omitted.

The transistor T_SP1 of the first sub-pixel SP1 may include a source area SRA, a drain area DRA, and a gate electrode GE.

The source area SRA and the drain area DRA may be disposed in the substrate SUB. Formed through, for example, an ion injection process, a well WL may be disposed in the substrate SUB. The source area SRA and the drain area DRA may be spaced apart from each other in the well WL. An area between the source area SRA and the drain area DRA in the well WL may be defined as a channel area.

The gate electrode GE may overlap the channel area between the source area SRA and the drain area DRA, and may be disposed in the pixel circuit layer PCL. The gate electrode GE may be spaced apart from the well WL or the channel area by an insulating material, such as a gate insulating layer GI. The gate electrode GE may include conductive material.

A plurality of layers included in the pixel circuit layer PCL may include insulating layers and conductive patterns disposed between the insulating layers. The conductive patterns may include first and second conductive patterns CP1 and CP2. The first conductive pattern CP1 may be electrically connected to the drain area DRA through a drain connector DRC passing through one or more insulating layers. The second conductive pattern CP2 may be electrically connected to the source area SRA through a source connector SRC passing through one or more insulating layers.

As the gate electrode GE and the first and second conductive patterns CP1 and CP2 may be electrically connected to other circuit elements and/or lines, the transistor T_SP1 of the first sub-pixel SP1 may be provided as one of the transistors of the first sub-pixel SP1.

Each of the transistor T_SP2 of the second sub-pixel SP2 and the transistor T_SP3 of the third sub-pixel SP3 may be configured in a same manner as the transistor T_SP1 of the first sub-pixel SP1. The substrate SUB and the pixel circuit layer PCL may include respective circuit elements of the first to third sub-pixels SP1 to SP3.

A via layer VIAL may be disposed on the pixel circuit layer PCL. The via layer VIAL may cover (or overlap in the third direction DR3) the pixel circuit layer PCL, and have an overall even (or planar) surface. The via layer VIAL may be configured to planarize stepped portions of the pixel circuit layer PCL. The via layer VIAL may include at least one of silicon oxide (SiOₓ), silicon nitride (SiNₓ), and silicon carbon nitride (SiCN), but embodiments are not limited to these example materials.

The light-emitting element layer LDL may be disposed on the via layer VIAL. The light-emitting element layer LDL may include first to third reflective electrodes RE1 to RE3, a planarization layer PLNL, first to third anode electrodes AE1 to AE3, a pixel defining layer PDL, an emission structure EMS, and a cathode electrode CE.

The first to third reflective electrodes RE1 to RE3 may be respectively disposed in the first to third sub-pixels SP1 to SP3 on the via layer VIAL. Each of the first to third reflective electrodes RE1 to RE3 may contact (e.g., physically and/or electrically) a circuit element disposed in the pixel circuit layer PCL through a corresponding via passing through the via layer VIAL.

The first to third reflective electrodes RE1 to RE3 may function as full mirrors provided to reflect light emitted from the emission structure EMS toward the display surface (or the cover window CW). The first to third reflective electrodes RE1 to RE3 may include metallic materials suitable for reflecting light. The first to third reflective electrodes RE1 to RE3 may include at least one of aluminum (Al), silver (Ag), magnesium (Mg), platinum (Pt), palladium (Pd), gold (Au), nickel (Ni), neodymium (Nd), iridium (Ir), chromium (Cr), and titanium (Ti), and/or an alloy of two or more materials selected from among the aforementioned materials, but embodiments are not limited to these examples.

In embodiments, a connection electrode may be disposed under each of the first to third reflective electrodes RE1 to RE3. The connection electrode may enhance electrical connection characteristics between the corresponding reflective electrode and the corresponding circuit element of the pixel circuit layer PCL. The connection electrode may have a multilayer structure. The multilayer structure may include at least one of titanium (Ti), titanium nitride (TiN), tantalum nitride (TaN), and the like, but embodiments are not limited to these example materials. In embodiment, a corresponding reflective electrode may be positioned between multiple layers of the connection electrode.

A buffer pattern BFP may be disposed under at least one of the first to third reflective electrodes RE1 to RE3. The buffer pattern BFP may include inorganic material, such as silicon carbon nitride, but embodiments are not limited to silicon carbon nitride. As the buffer pattern BFP is disposed, a height of the corresponding reflective electrode in the third direction DR3 may be adjusted. For example, the buffer pattern BFP may be disposed between the first reflective electrode RE1 and the via layer VIAL, thus adjusting a height of the first reflective electrode RE1 in the third direction DR3.

The first to third reflective electrodes RE1 to RE3 may function as full mirrors, and the cathode electrode CE may function as a half mirror. Light emitted from the emission layer of the emission structure EMS may be amplified at least partially by reciprocating between the corresponding reflective electrode and the cathode electrode CE. The amplified light can be output through the cathode electrode CE. The distance between each reflective electrode and the cathode electrode CE can be understood as a resonant distance for the light emitted from the emission layer of the corresponding emission structure EMS.

The first sub-pixel SP1 may have a resonant distance shorter than other sub-pixels due to the buffer pattern BFP. An adjusted resonant distance may make it possible for light in a specific wavelength range (e.g., red color light) to be efficiently amplified. The first sub-pixel SP1 may effectively and efficiently output light in the corresponding wavelength range.

In FIG. 18, there is illustrated a case in which the buffer pattern BFP is provided in the first sub-pixel SP1 and is not provided in the second and third sub-pixels SP2 and SP3, but embodiments are not limited to this example. The buffer pattern BFP may also be provided in at least one of the second and third sub-pixels SP2 and SP3 so that the resonant distance of at least one of the second and third sub-pixels SP2 and SP3 can be adjusted. For example, the first to third sub-pixels SP1 to SP3 may respectively correspond to red, green, and blue sub-pixels. A distance between the first reflective electrode RE1 and the cathode electrode CE in the third direction DR3 may be less than a distance between the second reflective electrode RE2 and the cathode electrode CE in the third direction DR3. A distance between the second reflective electrode RE2 and the cathode electrode CE in the third direction DR3 may be less than a distance between the third reflective electrode RE3 and the cathode electrode CE in the third direction DR3.

To planarize stepped portions between the first to third reflective electrodes RE1 to RE3, the planarization layer PLNL may be disposed on the via layer VIAL and the first to third reflective electrodes RE1 to RE3. The planarization layer PLNL may cover overall (or substantially overall) surfaces of the first to third reflective electrodes RE1 to RE3 and the via layer VIAL, and have an even (or planar) surface, such as a planar upper surface. In an embodiment, the planarization layer PLNL may be omitted.

On the planarization layer PLNL, the first to third anode electrodes AE1 to AE3 may be disposed, overlapping the first to third reflective electrodes RE1 to RE3, respectively in the third direction DR3. The first to third anode electrodes AE1 to AE3 may have shapes similar to the first to third emission areas EMA1 to EMA3 of FIG. 7 in a view in the third direction DR3. The first to third anode electrodes AE1 to AE3 may be respectively electrically connected to the first to third reflective electrodes RE1 to RE3. The first anode electrode AE1 may be electrically connected to the first reflective electrode RE1 through a first via VIA1 passing through the planarization layer PLNL. The second anode electrode AE2 may be electrically connected to the second reflective electrode RE2 through a second via VIA2 passing through the planarization layer PLNL. The third anode electrode AE3 may be electrically connected to the third reflective electrode RE3 through a third via VIA3 passing through the planarization layer PLNL.

In embodiments, the first to third anode electrodes AE1 to AE3 may include at least one transparent conductive material, such as at least one of indium tin oxide (ITO), indium zinc oxide (IZO), zinc oxide (ZnOₓ), indium gallium zinc oxide (IGZO), and indium tin zinc oxide (ITZO). However, the material of the first to third anode electrodes AE1 to AE3 is not limited to the aforementioned examples. For example, the first to third anode electrodes AE1 to AE3 may include titanium nitride or any other suitable material.

In embodiments, insulating layers may be further provided to adjust the heights of one or more of the first to third anode electrodes AE1 to AE3 in the third direction DR3. The insulating layers may be disposed between at least one of the first to third anode electrodes AE1 to AE3 and the corresponding reflective electrode. The planarization layer PLNL and/or the buffer pattern BFP may be omitted. For example, the first to third sub-pixels SP1 to SP3 may respectively correspond to red, green, and blue sub-pixels. A distance between the first anode electrode AE1 and the cathode electrode CE in the third direction DR3 may be less than a distance between the second anode electrode AE2 and the cathode electrode CE in the third direction DR3. A distance between the second anode electrode AE2 and the cathode electrode CE in the third direction DR3 may be less than a distance between the third anode electrode AE3 and the cathode electrode CE in the third direction DR3. The pixel defining layer PDL may be disposed on the planarization layer PLNL and portions of the first to third anode electrodes AE1 to AE3. The pixel defining layer PDL may include openings OP that expose respective portions of the first to third anode electrodes AE1 to AE3. The openings OP in the pixel defining layer PDL may define (or at least partially bound) the respective emission areas of the first to third sub-pixels SP1 to SP3. The pixel defining layer PDL may be placed (or disposed) in the non-emission area NEA of FIG. 15, and may define (or at least partially bound) the first to third emission areas EMA1 to EMA3 of FIG. 15.

In embodiments, the pixel defining layer PDL may include multiple inorganic insulating layers. Each of the inorganic insulating layers may include at least one of silicon oxide (SiOₓ) and silicon nitride (SiNₓ). For example, the pixel defining layer PDL may include first to third inorganic insulating layers that are successively stacked on one another in the third direction DR3. The first to third inorganic insulating layers may respectively include silicon nitride, silicon oxide, and silicon nitride. However, embodiments are not limited to these examples. The first to third insulating layers may have a stepped cross-section in an area adjacent to each of the openings OP, such as in FIG. 18.

The metal line JHLk may be provided in a boundary area BDA between adjacent sub-pixels, such as between the second sub-pixel SP2 and the third sub-pixel SP3. Each of the metal lines JHL1 to JHLo including the metal line JHLk may be positioned on the pixel defining layer PDL (refer also to FIG. 7).

Each of the metal lines JHL1 to JHLo including the metal line JHLk may contact (e.g., physically and/or electrically) the cathode electrodes CE of the light-emitting elements of the sub-pixels SP in the display area DA. For example, the metal lines JHL1 to JHLo may generate heat resulting from Joule heating after the emission structure EMS is formed through a stacking process, thus sublimating portions of the emission structure EMS positioned adjacent to the metal lines JHL1 to JHLo. In an embodiment including the emission structure EMS of FIG. 16, a Joule heating process may be performed after all of the first emission component EU1, the charge generation layer CGL, and the second emission component EU2 are stacked on one another. The emission structure EMS may not remain on the metal line JHLk. In an embodiment including the emission structure EMS′ of FIG. 17, a Joule heating process may be performed after all of the first emission component EU1′, the first charge generation layer CGL1′, the second emission component EU2′, the second charge generation layer CGL2′, and the third emission component EU3′ are stacked on one another. The emission structure EMS′ may not remain on the metal line JHLk. Current leakage through portions of the emission structure EMS separated by the metal lines JHL1 to JHLo can be prevented or at least mitigated. The metal lines JHL1 to JHLo may be exposed outside the emission structure EMS, and may contact (e.g., physically and/or electrically) the subsequently deposited cathode electrode CE.

The emission structure EMS may be disposed on the anode electrodes AE exposed through the openings OP in the pixel defining layer PDL. In embodiments, the emission structure EMS may be formed through a process, such as vacuum deposition, or inkjet printing. The emission structure EMS may be disposed in the openings OP of the pixel defining layer PDL, and may be disposed over the overall (or substantially overall) areas of the first to third sub-pixels SP1 to SP3. As described above, the emission structure EMS may be at least partially interrupted in the boundary area BDA by the metal line JHLk. During an operation of the display panel 110, current leaking from each of the first to third sub-pixels SP1 to SP3 to adjacent sub-pixel(s) through the layers included in the emission structure EMS may be reduced. The first to third light-emitting elements LD1 to LD3 may operate with relatively high reliability.

The cathode electrode CE may be disposed on the emission structure EMS. The cathode electrode CE may be provided in common in the first to third sub-pixels SP1 to SP3. The cathode electrode CE may function as a half mirror, partially transmitting and partially reflecting light emitted from the emission structure EMS.

The first anode electrode AE1, a portion of the emission structure EMS that overlaps the first anode electrode AE1 in the third direction DR3, and a portion of the cathode electrode CE that overlaps the first anode electrode AE1 in the third direction DR3 may form a first light-emitting element LD1. The second anode electrode AE2, a portion of the emission structure EMS that overlaps the second anode electrode AE2 in the third direction DR3, and a portion of the cathode electrode CE that overlaps the second anode electrode AE2 may form a second light-emitting element LD2. The third anode electrode AE3, a portion of the emission structure EMS that overlaps the third anode electrode AE3 in the third direction DR3, and a portion of the cathode electrode CE that overlaps the third anode electrode AE3 in the third direction DR3 may form a third light-emitting element LD3.

The encapsulation layer TFE may be disposed on the cathode electrode CE. The encapsulation layer TFE may prevent (or at least mitigate) oxygen, water, and/or the like from penetrating into the light-emitting element layer LDL.

The optical functional layer OFL may be disposed on the encapsulation layer TFE. In embodiments, the optical functional layer OFL may be attached to the encapsulation layer TFE through an adhesive layer APL. For example, the optical functional layer OFL may be fabricated through a separate process and attached to the encapsulation layer TFE by the adhesive layer APL. The adhesive layer APL may further perform a function of protecting underlying layers including the encapsulation layer TFE. It is also contemplated that the optical functional layer OFL may be formed on (e.g., directly on) the encapsulation layer TFE without the use of an adhesive.

The optical functional layer OFL may include a color filter layer CFL and a lens array LA. The color filter layer CFL may include first to third color filters CF1 to CF3 respectively corresponding to the first to third sub-pixels SP1 to SP3. The first to third color filters CF1 to CF3 may transmit light in different wavelength ranges from one another. For example, the first to third color filters CF1 to CF3 may respectively transmit red light, green light, and blue light.

In embodiments, the first to third color filters CF1 to CF3 may partially overlap each other in the third direction DR3 in the boundary area BDA. In some embodiments, the first to third color filters CF1 to CF3 may be spaced apart from each other, and a black matrix may be provided between the first to third color filters CF1 to CF3.

The lens array LA may be disposed on the color filter layer CFL. The lens array LA may include first to third lenses LS1 to LS3 that respectively correspond to the first to third sub-pixels SP1 to SP3. The first to third lenses LS1 to LS3 may respectively direct light emitted from the first to third light-emitting elements LD1 to LD3 in one or more intended paths, thus enhancing the light output efficiency.

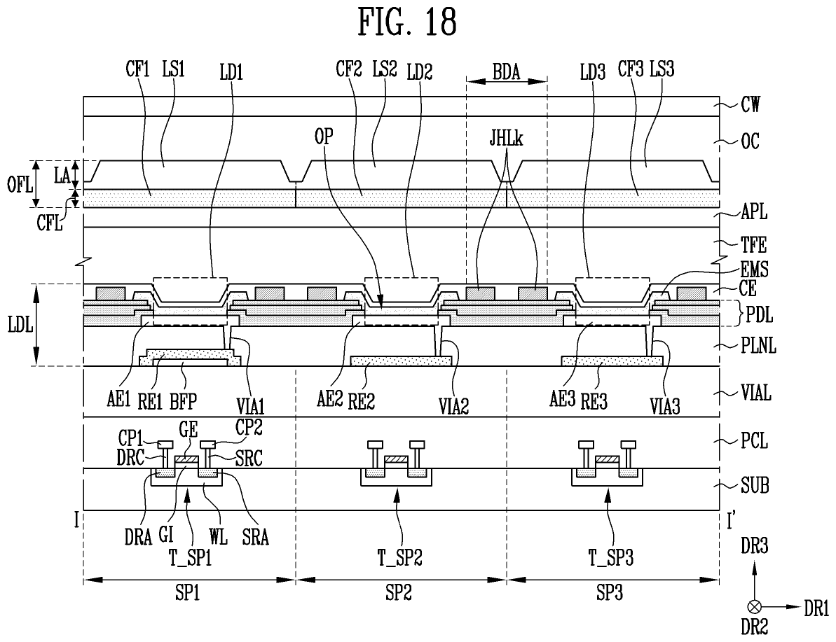

FIG. 19 is a sectional view schematically illustrating an embodiment of FIG. 18.

The emission structure EMS of FIG. 19 differs from the emission structure EMS of FIG. 18 in that a portion of the emission structure EMS remains on the metal line JHLk. Each of the metal lines JHL1 to JHLo including the metal line JHLk may not contact (e.g., physically and/or electrically) the cathode electrodes CE of the light-emitting elements of the sub-pixels SP in the display area DA.

For example, after the first emission component EU1 and the charge generation layer CGL are stacked on the metal line JHLk, heat generated from the metal line JHLk by Joule heating may sublimate portions of the first emission component EU1 and the charge generation layer CGL that are positioned adjacent to the metal line JHLk. Thereafter, stacking of the second emission component EU2 may be performed (refer to FIG. 16). The metal line JHLk may contact a residue of the second emission component EU2.

As another example, after the first emission component EU1′, the first charge generation layer CGL1′, the second emission component EU2′, and the second charge generation layer CGL2′ are stacked on the metal line JHLk, heat generated from the metal line JHLk by Joule heating may sublimate portions of the first emission component EU1′, the first charge generation layer CGL1′, the second emission component EU2′, and the second charge generation layer CGL2′ that are positioned adjacent to the metal line JHLk. Thereafter, stacking of the third emission component EU3′ may be performed (refer to FIG. 17). The metal line JHLk may contact a residue of the third emission component EU3′.

At least because the charge generation layer CGL, the first charge generation layer CGL1′, or the second charge generation layer CGL2′ having relatively high conductivity may sublimate, current leakage may be prevented (or at least mitigated) even in instances in which a portion of the emission structure EMS remains.

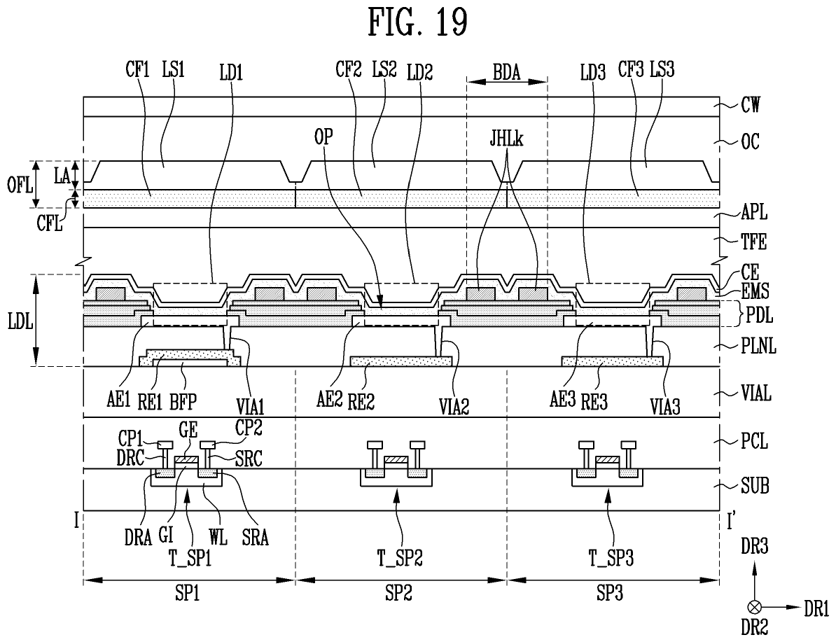

FIG. 20 is a schematic sectional diagram taken along sectional line A-A′ of FIG. 8 according to an embodiment.

Referring to FIG. 20, there is schematically illustrated cross-sectional structures of the first sub-metal pad SPDa12 and the additional pad PD13.

For example, a distance between the substrate SUB and the first sub-metal pad SPDa12 may be greater than a distance between the substrate SUB and the additional pad PD13. The distances may refer to distances in the third direction DR3. Although described with respect to the first sub-metal pad SPDa12 and the additional pad PD13, the same may be true with respect to the other first sub-metal pads (e.g., first sub-metal pads SPDa11, SPDa13, SPDa14, SPDa15, SPDa16, and SPDa17) and the other additional pads (e.g., additional pads PD11 and PD12).

The additional pads PD11, PD12, and PD13 may include (or may be part of) a first electrode layer. The first electrode layer may be one of electrode layers constituting the sub-pixel circuits SPC of the sub-pixels SP. For example, the first electrode layer may be a same electrode layer as the gate electrodes GE of the transistors or the first and second conductive patterns CP1 and CP2 (refer to FIGS. 18 and 19). The first electrode layer may be positioned in the pixel circuit layer PCL, and may be an electrode layer different from that of the gate electrode GE and the first and second conductive patterns CP1 and CP2. The additional pads PD11, PD12, and PD13 may include not only the first electrode layer, but also other electrode layers, thus forming a multilayer structure.

In an embodiment, the first sub-metal pads SPDa11, SPDa12, SPDa13, SPDa14, SPDa15, SPDa16, and SPDa17 may include a second electrode layer. The second electrode layer may be an electrode layer constituting the first to third anode electrodes AE1, AE2, and AE3 of the first to third light-emitting elements LD1, LD2, and LD3 of the first to third sub-pixels SP1, SP2, and SP3 (refer to FIGS. 18 and 19).

In an embodiment, the first sub-metal pads SPDa11, SPDa12, SPDa13, SPDa14, SPDa15, SPDa16, and SPDa17 may include a second electrode layer. The second electrode layer may be an electrode layer constituting the first to third reflective electrodes RE1, RE2, and RE3 positioned under the first to third light-emitting elements LD1, LD2, and LD3 of the first to third sub-pixels SP1, SP2, and SP3.

In an embodiment, the first sub-metal pads SPDa11, SPDa12, SPDa13, SPDa14, SPDa15, SPDa16, and SPDa17 may have a multilayer structure including an electrode layer constituting the first to third anode electrodes AE1, AE2, and AE3 and an electrode layer constituting the first to third reflective electrodes RE1, RE2, and RE3.

The pixel defining layer PDL and the planarization layer PLNL may include contact holes. The metal lines, such as metal line JHL(o-2), may contact the first sub-metal pads (e.g., first sub-metal pad SPDa12) through the contact holes.

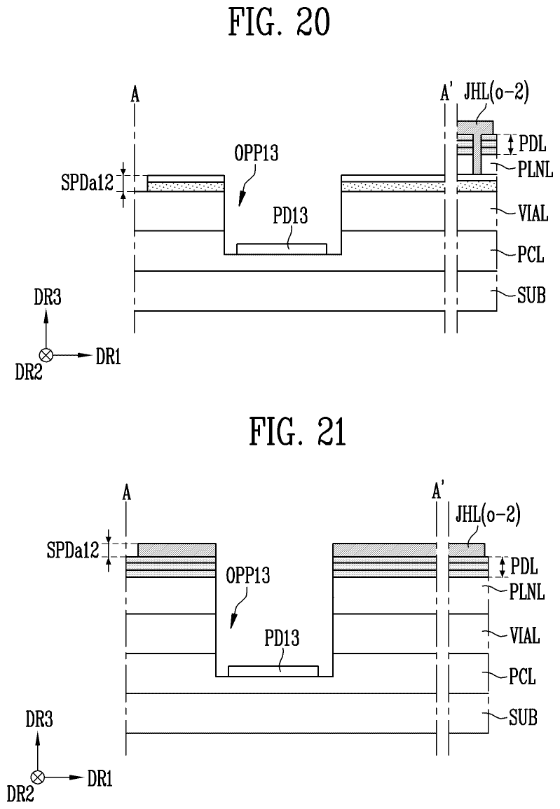

FIG. 21 is a sectional view schematically illustrating an embodiment of FIG. 20.

The configuration of the additional pads (such as additional pad PD13) in FIG. 21 may be equivalent to the configuration of the additional pads in FIG. 20. Redundant explanations will be omitted.

Referring to FIG. 21, the first sub-metal pads (such as first sub-metal pad SPDa12) may include a second electrode layer. The second electrode layer may be an electrode layer constituting the metal lines (such as metal line JHL(o-2)). The first sub-metal pads (such as first sub-metal pad SPDa12) and the metal lines (such as metal line JHL(o-2)) may be simultaneously (or substantially simultaneously) formed through a same process. Contact holes for contact (e.g., physical and/or electrical) between the first sub-metal pads (such as first sub-metal pad SPDa12) and the metal lines (such as metal line JHL(o-2)) may not be provided.

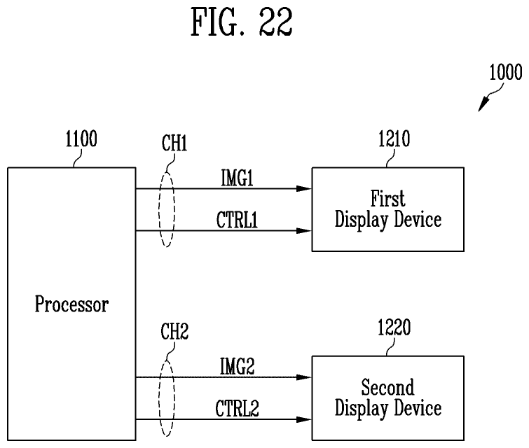

FIG. 22 is a block diagram schematically illustrating an embodiment of a display system.

Referring to FIG. 22, the display system 1000 may include a processor 1100, and one or more display devices, such as first and second display devices 1210 and 1220.

The processor 1100 may perform various tasks and operations. In embodiments, the processor 1100 may include an application processor, a graphic processor, a microprocessor, a central processing unit (CPU), and/or the like. The processor 1100 may be electrically connected to the other components of the display system 1000 through a bus system to control and/or communicate with the components.

In FIG. 22, the display system 1000 includes the first and second display devices 1210 and 1220. The processor 1100 may be electrically connected to the first display device 1210 through a first channel CH1, and may be electrically connected to the second display device 1220 through a second channel CH2.

The processor 1100 may transmit first image data IMG1 and a first control signal CTRL1 to the first display device 1210 through the first channel CH1. The first display device 1210 may display an image based on the first image data IMG1 and the first control signal CTRL1. The first display device 1210 may be configured in a same manner as the display device 100 described with reference to FIG. 1. The first image data IMG1 and the first control signal CTRL1 may be provided as the input image data IMG and the control signal CTRL of FIG. 1, respectively.

The processor 1100 may transmit second image data IMG2 and a second control signal CTRL2 to the second display device 1220 through the second channel CH2. The second display device 1220 may display an image based on the second image data IMG2 and the second control signal CTRL2. The second display device 1220 may be configured in a same manner as the display device 100 described with reference to FIG. 1. The second image data IMG2 and the second control signal CTRL2 may be provided as the input image data IMG and the control signal CTRL of FIG. 1, respectively.

The display system 1000 may include computing systems that provide an image display function, such as a portable computer, a mobile phone, a smart phone, a tablet personal computer (tablet PC), a smart watch, a watch phone, a portable multimedia player, a navigation system, an ultra-mobile personal computer (UMPC), and/or the like. Furthermore, the display system 1000 may include at least one of a head-mounted display (HMD), a virtual reality (VR) device, a mixed reality (MR) device, and an augmented reality (AR) device.

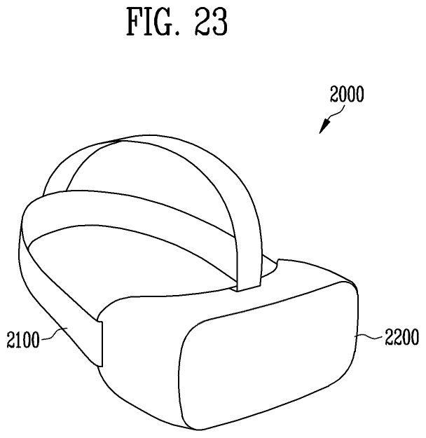

FIG. 23 is a perspective diagram schematically illustrating an application example of the display system 1000 of FIG. 22 according to an embodiment.

Referring to FIG. 23, the display system 1000 of FIG. 22 may be applied to a head-mounted display device 2000. The head mounted display device 2000 may be a wearable electronic device, which can be worn on the head of a user.

The head mounted display device 2000 may include a head-mounted band 2100 and a display device reception casing 2200. The head-mounted band 2100 may be connected to the display device reception casing 2200. The head-mounted band 2100 may include a horizontal band and/or a vertical band to fasten the head-mounted display device 2000 to the head of the user. The horizontal band may enclose (or abut) the sides of the head of the user, and the vertical band may enclose (or abut) the top of the head of the user. However, embodiments are not limited to the aforementioned example. For example, the head-mounted band 2100 may be implemented in the form of eyeglass frames, a helmet, etc.

The display device reception casing 2200 may receive (or support) the first and second display devices 1210 and 1220 of FIG. 22. The display device reception casing 2200 may further receive (or support) the processor 1100 of FIG. 22.

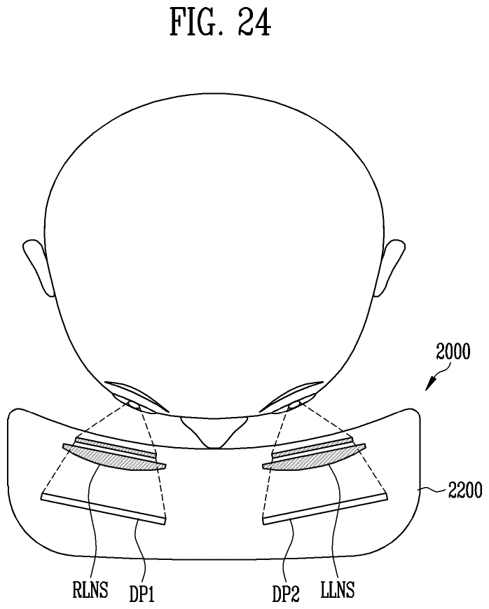

FIG. 24 is a diagram schematically illustrating the head-mounted display device of FIG. 23 that is worn by a user according to an embodiment.

Referring to FIG. 24, the first display panel DP1 of the first display device 1210 and the second display panel DP2 of the second display device 1220 may be disposed (or supported) in the head mounted display device 2000. The head mounted display device 2000 may further include one or more lenses, such as left-eye lens LLNS and right-eye lens RLNS.

In the display device reception casing 2200, the right-eye lens RLNS may be positioned between the first display panel DP1 and the right eye of the user. In the display device reception casing 2200, the left-eye lens LLNS may be positioned between the second display panel DP2 and the left eye of the user.

An image output from the first display panel DP1 can be viewed by the right eye of the user through the right-eye lens RLNS. The right-eye lens RLNS may refract light emitted from the first display panel DP1 toward the right eye of the user. The right-eye lens RLNS may perform an optical function to adjust a viewing distance between the first display panel DP1 and the right eye of the user.

An image output from the second display panel DP2 can be viewed by the left eye of the user through the left-eye lens LLNS. The left-eye lens LLNS may refract light emitted from the second display panel DP2 toward the left eye of the user. The left-eye lens LLNS may perform an optical function to adjust a viewing distance between the second display panel DP2 and the left eye of the user.

In embodiments, each of the right-eye lens RLNS and the left-eye lens LLNS may include an optical lens having a pancake-shaped cross-section. In embodiments, each of the right-eye lens RLNS and the left-eye lens LLNS may include a multi-channel lens including sub-areas having different optical characteristics. Each display panel may output images respectively corresponding to sub-areas of the multi-channel lens. The output images may be viewed by the user through the corresponding sub-areas.

As described, a display device in accordance with various embodiments may prevent (or at least mitigate) current leakage through a common layer between adjacent pixels.

Although the foregoing embodiments have been described in some detail for purposes of clarity of understanding, it will be apparent that certain changes and modifications may be practiced within the scope of the appended claims. It should be noted that there are many alternative ways of implementing the processes, systems, and apparatuses of the disclosed embodiments. Accordingly, embodiments are to be considered illustrative and not as restrictive, and embodiments are not to be limited to the details given herein.

What is claimed is:

1. A display device comprising:
a substrate including a display area and a non-display area;
a first metal pad disposed on the non-display area;
a second metal pad disposed on the non-display area, the second metal pad being spaced apart from the first metal pad in a first direction;
sub-pixels disposed on the display area, the sub-pixels being disposed between the first metal pad and the second metal pad in a view in third direction perpendicular to the substrate; and
metal lines electrically connecting the first metal pad to the second metal pad, the metal lines being disposed on the display area and spaced apart from light emission areas of the sub-pixels in the view, wherein
the first metal pad includes first sub-metal pads spaced apart from each other, and
the second metal pad includes second sub-metal pads spaced apart from each other.

2. The display device according to claim 1, wherein first sub-metal pads of a first group among the first sub-metal pads include openings.

3. The display device according to claim 2, wherein additional pads are respectively exposed through the openings.

4. The display device according to claim 3, wherein first sub-metal pads of a second group among the first sub-metal pads do not include openings.

5. The display device according to claim 4, wherein
second sub-metal pads of a first group among the second sub-metal pads include openings, and
some of the metal lines electrically connect the second sub-metal pads of the first group respectively to the first sub-metal pads of the first group.

6. The display device according to claim 5, wherein
second sub-metal pads of a second group among the second sub-metal pads do not include openings, and
some of the metal lines electrically connect the second sub-metal pads of the second group respectively to the first sub-metal pads of the second group.

7. The display device according to claim 6, further comprising:
a voltage generator configured to:
apply at least one first voltage pulse to each of the first sub-metal pads of the first group; and
apply at least one second voltage pulse to each of the first sub-metal pads of the second group.

8. The display device according to claim 7, wherein a voltage level of the at least one first voltage pulse is less than a voltage level of the at least one second voltage pulse.

9. The display device according to claim 8, wherein a number of the at least one first voltage pulse is greater than a number of the at least one second voltage pulse.

10. The display device according to claim 9, wherein the voltage generator is configured to set the voltage levels and the numbers of the at least one first voltage pulse and the at least one second voltage pulse such that a power density of each of the first sub-metal pads of the first group is identical to a power density of each of the first sub-metal pads of the second group.

11. The display device according to claim 8, wherein
the voltage generator is configured to apply a third voltage to the second sub-metal pads of the first group and the second sub-metal pads of the second group, and
a voltage level of the third voltage is less than the voltage level of the at least one first voltage pulse and the voltage level of the at least one second voltage pulse.

12. The display device according to claim 4, wherein
the first metal pad extends in a second direction transverse to the first direction, the third direction being perpendicular to the first direction and the second direction, and
a width of each of the first sub-metal pads of the first group in the second direction is less than a width of each of the first sub-metal pads of the second group in the second direction.

13. The display device according to claim 12, wherein
the second metal pad extends in the second direction, and
a width of each of the second sub-metal pads of the first group in the second direction is less than a width of each of the second sub-metal pads of the second group in the second direction.

14. The display device according to claim 3, wherein respective distances between the substrate and the first sub-metal pads in the third direction is greater than respective distances between the substrate and the additional pads in the third direction.

15. The display device according to claim 14, wherein
the additional pads include a first electrode layer, and
the first electrode layer is part of an electrode layer among electrode layers forming sub-pixel circuits of the sub-pixels.

16. The display device according to claim 15, wherein
the first sub-metal pads include a second electrode layer, and
the second electrode layer is part of an electrode layer forming anode electrodes of light-emitting elements of the sub-pixels.

17. The display device according to claim 15, wherein
the first sub-metal pads include a second electrode layer, and
the second electrode layer is part of an electrode layer forming reflective electrodes, the reflective electrodes being disposed between light-emitting elements of the sub-pixels and the substrate.

18. The display device according to claim 15, wherein
the first sub-metal pads include a second electrode layer, and
the second electrode layer is part of an electrode layer forming the metal lines.

19. The display device according to claim 1, wherein
the first metal pad extends in a second direction transverse to the first direction,
the first sub-metal pads are spaced apart from each other along the second direction, and
widths of the first sub-metal pads in the second direction are identical to each other.

20. The display device according to claim 19, wherein
the second metal pad extends in the second direction,
the second sub-metal pads are spaced apart from each other along the second direction, and
widths of the second sub-metal pads in the second direction are identical to each other.
